(19) United States
(12) Patent Application Publication
(10) Pub. No.: US 2015/0083193 A1
(43) Pub. Date: Mar. 26, 2015

(54) SECONDARY LENS, PHOTOVOLTAIC CELL MOUNTING BODY, CONCENTRATING PHOTOVOLTAIC POWER GENERATION UNIT, AND CONCENTRATING PHOTOVOLTAIC POWER GENERATION MODULE

(71) Applicant: SHARP KABUSHIKI KAISHA, Osaka-shi, Osaka (JP)

(72) Inventor: Kohsuke Ueda, Osaka-shi (JP)

(73) Assignee: SHARP KABUSHIKI KAISHA, OSaka-shi, Oaaka (JP)

(21) Appl. No.: 14/389,618

(22) PCT Filed: Mar. 28, 2013
(86) PCT No.: PCT/JP2013/059224

§ 371 Date: Sep. 30, 2014

(30) Foreign Application Priority Data
Mar. 30, 2012 (JP) 2012-082048
Jun. 28, 2012 (JP) 2012-146070

(51) Int. Cl. H01L 31/0232; H01L 31/054; H01L 31/0216

(52) U.S. Cl. CPC H01L 31/02325; H01L 31/02168; H01L 31/0543
USPC 136/246; 136/259; 136/256

(57) ABSTRACT

A secondary lens includes a first face on which a concentrated light beam output from a concentrating lens is incident and a second face from which the concentrated light beam output from the concentrating lens is output to a photovoltaic cell. The secondary lens guides incident light to the photovoltaic cell through an optical refractive face provided on the first face. A cross-sectional area of the first face in a direction perpendicular to an optical axis (Ax) of the concentrated light beam monotonically increases as the cross-sectional area approaches from a side of the first face closer to the concentrating lens to a side of the first face closer to the photovoltaic cell. At least one point of inflection at which an angle of inclination (θ) of the first face with respect to a plane perpendicular to the optical axis decreases as the angle of inclination (θ) approaches from the side of the first face closer to the concentrating lens to the side of the first face closer to the photovoltaic cell is provided.

### TECHNICAL FIELD

The present invention relates to a secondary lens used in a concentrating photovoltaic power generation module which applies light concentrated by concentrating lenses to photovoltaic cells, a photovoltaic cell mounting body on which this secondary lens is mounted, a concentrating photovoltaic power generation unit and a concentrating photovoltaic power generation apparatus using the photovoltaic cell mounting body, and a concentrating photovoltaic power generation module using the concentrating photovoltaic power generation apparatus.

### BACKGROUND ART

A photovoltaic power generation apparatus which converts solar energy into electrical power has been put to practical use. In order to reduce the cost and to obtain a greater magnitude of electrical power by further improving the photoelectric conversion efficiency (power generation efficiency), a concentrating photovoltaic power generation apparatus that generates electrical power by applying solar radiation concentrated by a concentrating lens to a photovoltaic cell, which is smaller than the concentrating lens, has been proposed.

A concentrating photovoltaic power generation apparatus concentrates solar radiation by using a concentrating lens. Accordingly, a photovoltaic cell may have a small light receiving area as long as it is capable of receiving solar radiation concentrated by an optical system by this light receiving area. That is, since the size of a photovoltaic cell may be smaller than the light receiving area of a concentrating lens, it is possible to reduce the size of a photovoltaic cell. This also means that the area occupied (used) by a photovoltaic cell, which is the most expensive component forming a photovoltaic power generation apparatus, is decreased, thereby making it possible to reduce the cost. Because of this advantage, a concentrating photovoltaic power generation apparatus is being utilized as a system for supplying electrical power in a location where a large area is available for generating power.

A first example of the related art will be described below with reference to FIGS. 18A and 18B, and a second example of the related art will be described below with reference to FIGS. 19A and 19B.

FIG. 18A is a plan view of a concentrating photovoltaic power generation apparatus 401 and a concentrating photovoltaic power generation module 401M, which serve as the first example of the related art, as viewed from concentrating lenses 402.

FIG. 18B is a sectional view of the concentrating photovoltaic power generation apparatus 401 and the concentrating photovoltaic power generation module 401M shown in FIG. 18A, taken along line 18B-18B indicated by the arrows in FIG. 18A.

In the concentrating photovoltaic power generation apparatus 401 (concentrating photovoltaic power generation module 401M), which serve as the first example of the related art (for example, see PTL 1), solar radiation (light Lc) is refracted and concentrated by Fresnel concentrating lenses 402, which serve as a primary light-concentration optical system, and the condensed light Lc is applied to photovoltaic cells 403, thereby performing photoelectric conversion (photovoltaic power generation). The concentrating photovoltaic power generation apparatus 401 (concentrating photovoltaic power generation module 401M) also includes a receiver substrate 404 on which each photovoltaic cell 403 is mounted, a holding plate 405 on which receiver substrates 404 are placed, a module frame 406 disposed between the holding plate 405 and the concentrating lenses 402 so as to position the holding plate 405 and the concentrating lenses 402, and a light-transmitting surface protective layer 407 which protects each photovoltaic cell 403 from environments, such as the humidity.

In the concentrating photovoltaic power generation apparatus 401, light Lc concentrated by the concentrating lens 402 is directly applied to the photovoltaic cell 403 through the light-transmitting surface protective layer 407. The angle at which the light Lc is refracted by the concentrating lens 402 differs depending on the wavelength component of the light Lc. It is thus difficult to precisely and efficiently concentrate the light Lc, and if a fixed-focal-length lens is used as the concentrating lens 402 in order to enhance the light-concentration efficiency, the light Lc is excessively concentrated on and around the center of the photovoltaic cell 403. This may reduce the long-term reliability of the photovoltaic cell 403 and the light-transmitting surface protective layer 407 and may also decrease the fill factor (FF), which is one of the factors representing the electrical characteristics of the photovoltaic cell 403.

Since the light Lc concentrated by the concentrating lens 402 is directly received by the photovoltaic cell 403, if there is a deviation of the angle of incidence of the light Lc or a positional displacement between the concentrating lens 402 and the photovoltaic cell 403, the output from the photovoltaic cell 403 is likely to be decreased.

Additionally, by considering the workability, the concentrating lens 402 is usually formed from a translucent resin material, such as PMMA (polymethyl methacrylate), a silicone resin, or polycarbonate. The refractive index of a translucent resin material varies depending on the temperature. Accordingly, the amount of light Lc that reaches the photovoltaic cell 403 fluctuates in accordance with a change in the ambient temperature, and thus, the output from the photovoltaic cell 403 is likely to be decreased.

As a measure taken to solve such problems, the second example of the related art (for example, see PTL 2) is known.

FIG. 19A is a plan view of a concentrating photovoltaic power generation apparatus 408 and a concentrating photovoltaic power generation module 408M, which serve as the second example of the related art, as viewed from concentrating lenses 402.

FIG. 19B is a schematic view illustrating a state in which light Lc is concentrated, by enlarging secondary glass 409 used in the concentrating photovoltaic power generation apparatus 408 and the concentrating photovoltaic power generation module 408M shown in FIG. 19A.

In the concentrating photovoltaic power generation apparatus 408, rod-like secondary glass 409 is added to the concentrating photovoltaic power generation apparatus 401 shown in FIG. 18A. Accordingly, in the concentrating photovoltaic power generation apparatus 408, after the light concentrated by the concentrating lens 402 is received by the upper surface of the secondary glass 409, it is directed toward the photovoltaic cell 403 while being subjected to total reflection on the lateral surfaces of the secondary glass 409 and is then applied to the photovoltaic cell 403 through the lower surface of the secondary glass 409.

In the concentrating photovoltaic power generation apparatus 408, as the light Lc incident on the secondary glass 409 advances through the secondary glass 409, the photonic mixing effect is exhibited. Accordingly, light with a small chromatic aberration or a small light distribution is output from the secondary glass 409. As a result, an improvement in the value of FF can be expected. Additionally, since the plane of incidence of the secondary glass 409 is formed larger than the plane of exit thereof, the tolerance for a deviation of the angle of incidence of the light Lc or a positional displacement between the concentrating lens 402 and the secondary glass 409 is effectively increased.

### CITATION LIST

### Patent Literature

PTL 1: Japanese Unexamined Patent Application Publication No. 2003-174183
PTL 2: Japanese Unexamined Patent Application Publication No. 2006-313809

### SUMMARY OF INVENTION

### Technical Problem

However, in order to achieve the advantages of the second example of the related art, the secondary glass 409 requires an optical path having a certain length, that is, the secondary glass 409 is required to be sufficiently high. In the second example of the related art, for example, the secondary glass 409 having a height of 40 mm is provided by way of example. Accordingly, in the concentrating photovoltaic power generation apparatus 408, the parts cost is increased due to the use of the secondary glass 409. Additionally, it is necessary to precisely adjust the position of the center of the secondary glass 409 to the center of the photovoltaic cell 403, and then, the secondary glass 409 is mounted on the photovoltaic cell 403. Accordingly, a holding member for holding the secondary glass 409 is required, which increases the number of steps for manufacturing the concentrating photovoltaic power generation apparatus 408. In this manner, there are multiple problems in terms of the cost.

Additionally, due to the transmittance of the secondary glass 409, loss incurred while the light is being subjected to total reflection on the secondary glass 409, and optical loss incurred in a gap between the plane of exit of the secondary glass 409 and the photovoltaic cell 403, the output current of the photovoltaic cell 403 is decreased.

Accordingly, it is an object of the present invention to provide a secondary lens that is capable of improving the power generation efficiency of a photovoltaic cell by efficiently concentrating solar radiation (light) on a light receiving surface of the photovoltaic cell while suppressing a decrease in electrical characteristics (FF) of the photovoltaic cell by decreasing excessive concentration of light.

It is another object of the present invention to provide a photovoltaic cell mounting body, a concentrating photovoltaic power generation unit, a concentrating photovoltaic power generation apparatus, or a concentrating photovoltaic power generation module in which the electrical characteristics or the productivity of photovoltaic cells are improved by using the secondary lens of the present invention.

### Solution to Problem

A secondary lens of the present invention is a secondary lens used in a concentrating photovoltaic power generation module which applies light concentrated by a concentrating lens to a photovoltaic cell. The secondary lens includes: a first face which opposes the concentrating lens and on which a concentrated light beam output from the concentrating lens is incident; and a second face which opposes the photovoltaic cell and from which the concentrated light beam output from the concentrating lens is output. The secondary lens guides incident light to the photovoltaic cell through a refractive face provided on the first face. A cross-sectional area of the first face in a direction perpendicular to an optical axis of the concentrated light beam monotonically increases as the cross-sectional area approaches from a side of the first face closer to the concentrating lens to a side of the first face closer to the photovoltaic cell. At least one point of inflection at which an angle of inclination of the first face with respect to a plane perpendicular to the optical axis decreases as the angle of inclination approaches from the side of the first face closer to the concentrating lens to the side of the first face closer to the photovoltaic cell is provided.

With this configuration, by providing a step portion where the gradient of the optical refractive face starts to become gentle in a half way through the dome-shaped secondary lens, the concentration of light on the surface of the photovoltaic cell can be decreased. That is, by uniformly applying light to the surface of the photovoltaic cell, the power generation efficiency (conversion efficiency) of the photovoltaic cell can be improved.

In the secondary lens of the present invention, a line passing through the point of inflection may be positioned outside the photovoltaic cell, as viewed from above in a direction of the optical axis.

By positioning a line passing through the point of inflection (line of inflection) on the outside of the photovoltaic cell as viewed from above, the concentration of light on the surface of the photovoltaic cell can be decreased. That is, by uniformly applying light to the surface of the photovoltaic cell, the power generation efficiency (conversion efficiency) of the photovoltaic cell can be improved.

In the secondary lens of the present invention, a cross-sectional configuration of the optical refractive face provided on the first face in a region from a vertex portion of the first face which opposes the concentrating lens to a line passing through the point of inflection in a direction perpendicular to the optical axis may be similar to a cross-sectional configuration of an optical refractive face of the concentrating lens in a direction perpendicular to the optical axis.

In this manner, by forming the cross-sectional configuration of the optical refractive face provided on the first face in a region from the vertex portion of the first face which opposes the concentrating lens to a line passing through the point of inflection in a direction perpendicular to the optical axis to be similar to the cross-sectional configuration of the optical refractive face of the concentrating lens in a direction perpendicular to the optical axis, it is possible to concentrate light output from the concentrating lens toward the optical axis, and also, to decrease the concentration of light on the surface of the photovoltaic cell. That is, by uniformly applying light to the surface of the photovoltaic cell, the power generation efficiency (conversion efficiency) of the photovoltaic cell can be improved.

In the secondary lens of the present invention, a cross-sectional configuration of the optical refractive face provided on the first face in part of a region from a line passing through the point of inflection to the second face in a direction perpendicular to the optical axis may not be similar to a cross-sectional configuration of an optical refractive face of the concentrating lens in a direction perpendicular to the optical axis.

In this manner, by forming the cross-sectional configuration of the optical refractive face provided on the first face in part of a region from a line passing through the point of inflection to the second face in a direction perpendicular to the optical axis not to be similar to the cross-sectional configuration of the optical refractive face of the concentrating lens in a direction perpendicular to the optical axis, light incident on the region which is not similar to the cross-sectional configuration of the optical refractive face of the concentrating lens can be refracted in a horizontal direction in which it is separated from the optical axis (optical axis point), as viewed from above. Accordingly, the effect of dispersing light to be incident on the surface of the photovoltaic cell and decreasing the concentration of light on the surface of the photovoltaic cell can be obtained, thereby making it possible to further uniformly apply solar radiation to the surface of the photovoltaic cell.

In the secondary lens of the present invention, the photovoltaic cell may be a multi-junction photovoltaic cell, and light of a wavelength range corresponding to a portion of the photovoltaic cell having sensitivity to a short wavelength may not be incident on a region from a line passing through the point of inflection of the first face to the second face. In this case, “light is not incident” means that in terms of design, light of this wavelength range is not incident on the above-described region. Depending on the actual operating environment, however, a small amount of light may be incident due to, for example, a change in the ambient temperature or manufacturing errors. However, such an amount of incident light may be safely negligible. That is, in terms of design, the point of inflection is formed at a position outside a range in which light of a short wavelength range is incident. With this configuration, light of a wavelength range corresponding to the photovoltaic cell having sensitivity to a short wavelength is incident on the first optical refractive face H2a, but is not incident (strictly speaking, it is hardly incident) on the second optical refractive face H2b. Thus, light of a wavelength range to be incident on the surface of the photovoltaic cell having sensitivity to a short wavelength can be efficiently concentrated, and then, it is applied to the photovoltaic cell.

In the secondary lens of the present invention, the photovoltaic cell may be a multi-junction photovoltaic cell, and a position of the point of inflection in a height direction of the secondary lens may be set such that light of a specific wavelength which is output from an end of the concentrating lens and which is incident on a portion above and near the point of inflection reaches the photovoltaic cell after crossing the optical axis and such that light of a specific wavelength which is output from an end of the concentrating lens and which is incident on a portion below and near the point of inflection reaches the photovoltaic cell before crossing the optical axis.

In this case, light of a specific wavelength is distributed such that light incident on a portion above the point of inflection advances in a direction in which it crosses the optical axis and such that light of the specific wavelength incident on a portion below the point of inflection advances in a direction in which it does not cross the optical axis. Thus, the concentration of light on and around the center of the surface of the photovoltaic cell can be decreased, and also, light can be uniformly applied to the surface of the photovoltaic cell, thereby improving the power generation efficiency (conversion efficiency).

In the secondary lens of the present invention, the specific wavelength may be 650 to 900 nm. With this configuration, it is possible to decrease the concentration of light of a medium wavelength range on and around the center of the surface of the photovoltaic cell having sensitivity to a medium wavelength range and to uniformly apply light to the surface of the photovoltaic cell having sensitivity to a medium wavelength range, thereby making it possible to increase the power generation efficiency (conversion efficiency).

In the secondary lens of the present invention, a distance from the point of inflection to the photovoltaic cell may be set to be half or more of a distance from a vertex of the first face to the photovoltaic cell.

In this manner, by setting the distance from the point of inflection to the photovoltaic cell to be half or more of the distance from the vertex of the first face to the photovoltaic cell, the point of inflection can be provided at the upper side (closer to the vertex side) where the light-concentration efficiency is decreased. With this configuration, it is possible to decrease the concentration of light incident on the region from the point of inflection to the second face and to uniformly apply light to the surface of the photovoltaic cell, thereby making it possible to increase the power generation efficiency (conversion efficiency).

In the secondary lens of the present invention, an intermediate region which does not optically contribute to guiding of the incident light to the photovoltaic cell may be provided between the first face and the second face.

In this manner, the intermediate region, which does not optically contribute, is provided between the first face (light incoming section) and the second face (light outgoing section) of the secondary lens. Because of the provision of the intermediate region, when bonding and fixing the secondary lens to the photovoltaic cell and the receiver substrate, even if the light-transmitting filler adheres to a lateral surface of the secondary lens, that is, to the intermediate region, the output characteristics of the photovoltaic cell are not influenced at all.

In the secondary lens of the present invention, an antireflection coat for reducing surface reflection may be disposed on a surface of the first face.

With this configuration, it is possible to reduce loss caused by surface reflection when light is incident on the secondary lens, thereby improving the output of the photovoltaic cell.

A photovoltaic cell mounting body of the present invention is a photovoltaic cell mounting body including: a secondary lens on which light concentrated by a concentrating lens is incident; a photovoltaic cell which is disposed opposite the secondary lens and which performs photoelectric conversion on light output from the secondary lens; and a receiver substrate on which the photovoltaic cell is mounted. The secondary lens is the secondary lens configured as described above. A filling portion in which a translucent resin material is filled is disposed between the secondary lens and the photovoltaic cell.

In the photovoltaic cell mounting body of the present invention, a translucent resin material is filled between the secondary lens and the photovoltaic cell so as to form a filling portion, and an air space between the secondary lens and the photovoltaic cell is eliminated. With this configuration, since the reflection of light at the interface between the secondary lens and an air space can be suppressed, light output from the secondary lens can be efficiently guided to the photovoltaic cell, thereby enhancing the light-concentration efficiency and further improving the power generation efficiency (conversion efficiency).

A concentrating photovoltaic power generation unit of the present invention is a concentrating photovoltaic power generation unit including: a concentrating lens which concentrates light; a secondary lens from which light incident from the concentrating lens is output; and a photovoltaic cell which performs photoelectric conversion on light output from the secondary lens. The secondary lens is the secondary lens configured as described above.

In the concentrating photovoltaic power generation unit of the present invention, light incident on the secondary lens can be efficiently concentrated around the optical axis, and also, the excessive concentration of light can be decreased, thereby enhancing the light-concentration efficiency (conversion efficiency) of the photovoltaic cell.

A concentrating photovoltaic power generation module of the present invention is a concentrating photovoltaic power generation module formed by combining a plurality of concentrating photovoltaic power generation units. Each of the concentrating photovoltaic power generation units is the concentrating photovoltaic power generation unit configured as described above.

In the concentrating photovoltaic power generation module of the present invention, it is possible to improve the power generation efficiency (conversion efficiency) of the photovoltaic cell.

A secondary lens of the present invention is a secondary lens used in a concentrating photovoltaic power generation apparatus that includes a photovoltaic cell and a concentrating lens which concentrates light and applies the light to the photovoltaic cell. The secondary lens includes: a light incoming section on which the light is incident; and a light outgoing section from which the light incident on the light incoming section is output to the photovoltaic cell. The light incoming section includes a vertex portion which opposes the concentrating lens, and an intermediate portion positioned between the vertex portion and the light outgoing section. An area of a cross section of the intermediate portion in a direction perpendicular to a vertical axis which is defined by a straight line passing through a center of the concentrating lens and a center of the photovoltaic cell increases as the area of the cross section approaches from the vertex portion toward the light outgoing section. An outer peripheral configuration of at least some cross sections of the intermediate portion is different from a similar figure of an edge configuration of a cross section obtained by cutting an optical refractive face of the concentrating lens in a plane perpendicular to the vertical axis.

Thus, in the secondary lens of the present invention, the cross-sectional area of the intermediate portion in a direction perpendicular to the vertical axis which is defined by a straight line passing through the center of the concentrating lens and the center of the photovoltaic cell increases as it approaches from the vertex portion toward the light outgoing section. Additionally, the outer peripheral configuration of at least some cross sections is different from a similar figure of the edge configuration of a cross section obtained by cutting through the optical refractive face of the concentrating lens in a plane perpendicular to the vertical axis. With these configurations, the light concentrated by the concentrating lens toward the secondary lens is refracted by the outer peripheral configuration of the intermediate portion, thereby preventing the light from being excessively concentrated on and around the photovoltaic cell. As a result, it is possible to suppress a decrease in FF (fill factor) which indicates the electrical characteristics of the photovoltaic cell and to improve the power generation efficiency of the photovoltaic cell.

In the secondary lens of the present invention, the outer peripheral configuration may be a polygon.

Thus, in the secondary lens of the present invention, since the outer peripheral configuration is a polygon, a large amount of concentrated light can be refracted on the individual sides of the polygon, thereby reliably decreasing the excessive concentration of light and further suppressing a decrease in the value of FF.

In the secondary lens of the present invention, the outer peripheral configuration may include straight lines and curved lines, and the straight lines may make up half or more of an outer peripheral length of the outer peripheral configuration.

Accordingly, in the secondary lens of the present invention, the light concentrated by the concentrating lens toward the secondary lens can be refracted by the straight lines of the outer peripheral configuration. Thus, even if the outer peripheral configuration is not a polygon, the light is refracted by the straight lines, which make up half or more of the outer peripheral length, thereby reliably preventing the excessive concentration of the concentrated light on and around the center of the photovoltaic cell. As a result, a decrease in the concentration of light is implemented.

In the secondary lens of the present invention, at least part of a surface of the intermediate portion may be a plane.

Accordingly, in the secondary lens of the present invention, since the surface of the intermediate portion includes a plane, the outer peripheral configuration of a cross section of the intermediate portion can be made different from a similar figure of the edge configuration of a cross section of the concentrating lens in a plane perpendicular to the vertical axis.

In the secondary lens of the present invention, at least part of a surface of the intermediate portion may be a curved surface.

Accordingly, in the secondary lens of the present invention, since the surface of the intermediate portion includes a curved surface, part of the light concentrated toward the photovoltaic cell can be efficiently guided to the photovoltaic cell, thereby suppressing a decrease in the output current caused by a deviation of the angle of incident light or an error in assembling the photovoltaic cell and thereby increasing the amount of power generation of the photovoltaic cell.

In the secondary lens of the present invention, the outer peripheral configuration of the curved surface closer to the vertex portion may be circular about the vertical axis.

Accordingly, in the secondary lens of the present invention, since the outer peripheral configuration of the intermediate portion of a cross section closer to the vertex portion is circular about the vertical axis, the light-concentration efficiency becomes high in the central region of the secondary lens on which light is most intensively concentrated, thereby improving the light-concentration precision and suppressing a decrease in the output current. As a result, the amount of power generation of the photovoltaic cell can be improved.

In the secondary lens of the present invention, at least part of the outer peripheral configuration may be a segment forming part of a circle about the vertical axis.

Accordingly, in the secondary lens of the present invention, since part of the outer peripheral configuration is a segment forming part of a circle about the vertical axis, the light concentrated by the concentrating lens can be efficiently guided to the photovoltaic cell, thereby suppressing a decrease in the output current caused by a deviation of the angle of incident light or an assembling error. At the same time, the concentration of the light is decreased by refraction at portions other than the segments. As a result, the power generation efficiency of the photovoltaic cell can further be improved.

In the secondary lens of the present invention, a surface of the intermediate portion may have a ridge line and the ridge line may be chamfered.

Accordingly, in the secondary lens of the present invention, since a ridge line of the intermediate portion is chamfered, it is possible to prevent optical loss caused by scattering of light on the ridge line and to prevent the occurrence of damage when handling the secondary lens in a manufacturing process.

In the secondary lens of the present invention, an outer peripheral configuration of the cross section of the intermediate portion closer to the vertex portion may not be similar to an outer peripheral configuration of the cross section of the intermediate portion closer to the light outgoing section.

With this configuration, in the secondary lens of the present invention, the optical characteristics of the intermediate portion closer to the vertex portion are made different from those of the intermediate portion closer to the light outgoing section. Accordingly, by utilizing characteristics in which the position at which light refracted by the concentrating lens is incident varies in accordance with the wavelength, the balance between a decrease in the concentration of light and an increase in the light-concentration efficiency can be maintained.

In the secondary lens of the present invention, a gradient of a surface of the intermediate portion closer to the light outgoing section may be greater than a gradient of a surface of the intermediate portion closer to the vertex portion.

Accordingly, in the secondary lens of the present invention, since the gradient of the surface of the intermediate portion closer to the light outgoing section is greater than that of the intermediate portion closer to the vertex portion, light, which would reach a position far away from the center of the photovoltaic cell (light-receiving surface) if the secondary lens were not disposed, is refracted at a sharper angle toward the photovoltaic cell in a direction toward the vertical axis, thereby improving the light-concentration efficiency. Additionally, light is refracted by both of the intermediate portion closer to the vertex portion and the intermediate portion closer to the light outgoing section which have different gradients, so as to change the focal position in the direction of the vertical axis, thereby making it possible to decrease the concentration of light in a direction of the vertical axis Ax (vertical direction).

In the secondary lens of the present invention, a first angle of inclination, which is an angle of surface inclination of the intermediate portion closer to the light outgoing section, may be greater than a second angle of inclination, which is an angle of surface inclination of the intermediate portion closer to the vertex portion.

Accordingly, in the secondary lens of the present invention, since the first angle of inclination of the surface of the intermediate portion closer to the light outgoing section is greater than the second angle of inclination of the surface of the intermediate portion closer to the vertex portion, light, which would reach a position far away from the photovoltaic cell without the secondary lens, is refracted at a sharper angle, thereby improving the light-concentration efficiency.

In the secondary lens of the present invention, the vertex portion may be a plane.

Accordingly, in the secondary lens of the present invention, since the vertex portion is a plane, the secondary lens reliably guides light concentrated toward the photovoltaic cell to the photovoltaic cell without excessively refracting the light, thereby improving the light-concentration efficiency. It is also possible to decrease the concentration of light exhibited by the lens effect of the secondary lens, thereby further suppressing a decrease in the value of FF.

In the secondary lens of the present invention, the vertex portion may be a convex-shaped curved surface.

Accordingly, in the secondary lens of the present invention, since the vertex portion is a curved surface, the secondary lens efficiently guides light concentrated on the vertex portion by the concentrating lens to the photovoltaic cell while decreasing the concentration of light as a whole. It is thus possible to suppress a decrease in the value of FF and to suppress a decrease in the output current caused by a deviation of the angle of incidence of the light or a positional displacement of the photovoltaic cell, thereby increasing the amount of power generation of the photovoltaic cell.

The secondary lens of the present invention may further include a base portion which is disposed between the light outgoing section and the intermediate portion and which is integrally formed with the intermediate portion.

Accordingly, since the secondary lens of the present invention includes the base portion which is disposed between the light outgoing section and the intermediate portion and which is integrally formed with the intermediate portion, the secondary lens can be handled through the use of the base portion. It is thus possible to facilitate the handling and molding of the secondary lens in a manufacturing process without impairing the optical characteristics of the secondary lens, thereby rationalizing the manufacturing process and improving the production efficiency. As a result, a cost reduction in the parts can be achieved.

In the secondary lens of the present invention, an outer periphery of each of the light outgoing section and the base portion may be a quadrilateral.

Accordingly, in the secondary lens of the present invention, since the outer peripheries of the light outgoing section and the base portion are formed in a quadrilateral, it is possible to perform manufacturing by efficiently arranging multiple secondary lenses in a manufacturing process. Thus, the production efficiency can be improved, thereby achieving a cost reduction in the parts.

In the secondary lens of the present invention, the base portion may have a height of 0.5 mm or greater.

With this configuration, in the secondary lens of the present invention, a certain thickness of the secondary lens is secured by setting the height of the base portion (the length between the side of the intermediate portion closer to the base portion and the light outgoing section (the thickness of the base portion)) to be 0.5 mm or greater. Thus, it is less likely to cause faults, such as chipping, while handling the secondary lens 100 by using a jig. Additionally, in the secondary lens of the present invention, when the secondary lens is brought to oppose the photovoltaic cell with a light-transmitting material (light-transmitting-material filling portion) therebetween, even if a light-transmitting material adheres to a lateral surface (base portion), optical loss does not occur.

In the secondary lens of the present invention, an antireflection coat may be disposed on a surface of the light incoming section.

Accordingly, in the secondary lens of the present invention, since an antireflection coat is disposed on the surface of the light incoming section, the secondary lens can prevent the concentrated light from being reflected on the surface of the light incoming section and reduce loss caused by surface reflection, thereby improving the output of the photovoltaic cell.

In the secondary lens of the present invention, the secondary lens may be formed from a light-transmitting optical material and an refractive index of the light-transmitting optical material with respect to a D line may be greater than 1.35 and smaller than 1.80, and an absolute value of temperature dependence of the refractive index may be smaller than 1×10⁻⁴.

Accordingly, in the secondary lens of the present invention, since the refractive index ranges from 1.35 to 1.80, the advantages of the secondary lens as a refracting element can be obtained, and the reflectance on the surface can be reduced, thereby maintaining the light-concentration efficiency at a high level. Additionally, even if the refractive index is changed due to a temperature rise accompanied by light concentration, fluctuations in the light-concentration characteristics can be suppressed, thereby securing stable optical characteristics and maintaining high efficiency.

A photovoltaic cell mounting body of the present invention is a photovoltaic cell mounting body including: a secondary lens on which light concentrated by a concentrating lens is incident; a photovoltaic cell which is disposed opposite the secondary lens and which performs photoelectric conversion on light output from the secondary lens; and a receiver substrate on which the photovoltaic cell is mounted. The secondary lens is the secondary lens of the present invention. A light-transmitting material filling portion in which a light-transmitting material is filled is disposed between the secondary lens and the photovoltaic cell.

Accordingly, since the photovoltaic cell mounting body of the present invention includes the light-transmitting-material filling portion in which a light-transmitting material is filled between the secondary lens and the photovoltaic cell, it eliminates an air space between the secondary lens and the photovoltaic cell. With this configuration, since the reflection of light at the interface between the secondary lens and an air space can be suppressed, light output from the secondary lens can be efficiently guided to the photovoltaic cell, thereby enhancing the electrical characteristics of the photovoltaic cell.

In the photovoltaic cell mounting body of the present invention, the light-transmitting material filling portion may have a thickness of 0.3 mm to 2 mm.

Accordingly, in the photovoltaic cell mounting body of the present invention, since the thickness of the light-transmitting-material filling portion formed between the secondary lens and the photovoltaic cell is 0.3 mm to 2 mm, the controllability in a manufacturing process can be secured, and optical loss in the light-transmitting-material filling portion can be reduced, thereby preventing a decrease in the light-guiding efficiency. As a result, required electrical characteristics can be secured.

A concentrating photovoltaic power generation apparatus of the present invention is a concentrating photovoltaic power generation apparatus including: a concentrating lens which concentrates light; a secondary lens from which light incident from the concentrating lens is output; and a photovoltaic cell which performs photoelectric conversion on light output from the secondary lens. The secondary lens is the secondary lens of the present invention.

Accordingly, in the concentrating photovoltaic power generation apparatus of the present invention, even if there is a deviation of the angle of incident light or an error in positioning the photovoltaic cell, light incident on the secondary lens can be efficiently concentrated, and also, the excessive concentration of light can be prevented. It is thus possible to enhance the power generation efficiency of the photovoltaic cell and to improve the electrical characteristics.

In the concentrating photovoltaic power generation apparatus of the present invention, in a case in which a dimension of a side of the concentrating lens in a direction perpendicular to the vertical axis is indicated by L1, in which a dimension of the photovoltaic cell (dimension of a side of the cell) in a direction perpendicular to the vertical axis is indicated by L2, and in which a work distance between the concentrating lens and the photovoltaic cell is indicated by Wd, Dd may be greater than Wd·L2/L1 by 1.2 to 1.8, where Dd is a secondary light-concentration distance from a point at which a vertex portion of the secondary lens intersects with the vertical axis to a light-receiving surface of the photovoltaic cell.

Thus, in the concentrating photovoltaic power generation apparatus of the present invention, it is possible to concentrate light incident on the secondary lens with high efficiency and to prevent the excessive concentration of light with high precision, thereby enhancing the power generation efficiency of the photovoltaic cell and improving the electrical characteristics.

A concentrating photovoltaic power generation module of the present invention is a concentrating photovoltaic power generation module formed by combining a plurality of concentrating photovoltaic power generation apparatuses. Each of the concentrating photovoltaic power generation apparatuses is the concentrating photovoltaic power generation apparatus of the present invention. A plurality of the concentrating lenses are disposed on a single light-transmitting substrate and a plurality of the photovoltaic cells are disposed on a single holding plate.

Accordingly, in the concentrating photovoltaic power generation module of the present invention, positioning of the concentrating lenses is performed on the single light-transmitting substrate, and positioning of the photovoltaic cells is performed on the single holding plate. In this manner, by uniformly performing positioning of the concentrating lenses and the photovoltaic cells, the concentrating photovoltaic power generation module in which the concentrating lenses and the photovoltaic cells are highly precisely positioned can be easily manufactured. As a result, the productivity is improved, thereby reducing the manufacturing cost, and also, the electrical characteristics are improved.

In the concentrating photovoltaic power generation module of the present invention, the plurality of photovoltaic cells may be each mounted on a receiver substrate, and a plurality of the receiver substrates may be mounted on the holding plate.

Accordingly, the concentrating photovoltaic power generation module of the present invention is manufactured by mounting the individual photovoltaic cells on the respective receiver substrates, thereby making it easy to handle the photovoltaic cells. As a result, the operability is enhanced, thereby further improving the productivity.

### Advantageous Effects of Invention

In the secondary lens of the present invention, by providing a step portion where the gradient starts to become gentle in a half way through the secondary lens, the concentration of light on the surface of a photovoltaic cell can be decreased. That is, by uniformly applying light to the surface of the photovoltaic cell, the power generation efficiency (conversion efficiency) of the photovoltaic cell can be improved.

In the photovoltaic cell mounting body of the present invention, a translucent resin material is filled between the secondary lens and the photovoltaic cell so as to form a filling portion, and an air space between the secondary lens and the photovoltaic cell is eliminated. With this configuration, since the reflection of light at the interface between the secondary lens and an air space can be suppressed, light output from the secondary lens can be efficiently guided to the photovoltaic cell, thereby enhancing the light-concentration efficiency and further improving the power generation efficiency (conversion efficiency).

In the concentrating photovoltaic power generation unit of the present invention, light incident on the secondary lens can be efficiently concentrated around the optical axis, and also, the excessive concentration of light can be decreased, thereby enhancing the light-concentration efficiency (conversion efficiency) of the photovoltaic cell.

In the concentrating photovoltaic power generation module of the present invention, it is possible to improve the power generation efficiency (conversion efficiency) of the photovoltaic cell.

In the secondary lens of the present invention, the cross-sectional area of the intermediate portion increases as it approaches from the vertex portion toward the light outgoing section. Additionally, the outer peripheral configuration of at least some cross sections is different from a similar figure of the edge configuration of a cross section obtained by cutting through the optical refractive face of the concentrating lens in a plane perpendicular to the vertical axis.

Accordingly, in the secondary lens of the present invention, light concentrated by the concentrating lens toward the secondary lens is refracted by the outer peripheral configuration of the intermediate portion, thereby preventing light from being excessively concentrated on and around the photovoltaic cell. As a result, it is possible to suppress a decrease in FF (fill factor) which indicates the electrical characteristics of the photovoltaic cell and to improve the power generation efficiency of the photovoltaic cell.

The photovoltaic cell mounting body of the present invention includes a light-transmitting-material filling portion in which a light-transmitting material is filled between the secondary lens of the present invention and the photovoltaic cell.

Accordingly, in the photovoltaic cell mounting body of the present invention, an air space is eliminated between the secondary lens of the present invention and the photovoltaic cell. With this configuration, since the reflection of light at the interface between the secondary lens and an air space can be suppressed, light output from the secondary lens can be efficiently guided to the photovoltaic cell, thereby achieving the advantage of enhancing the electrical characteristics of the photovoltaic cell.

The concentrating photovoltaic power generation apparatus of the present invention includes the secondary lens of the present invention.

Accordingly, in the concentrating photovoltaic power generation apparatus of the present invention, even if there is a deviation of the angle of incident light or an error in positioning the photovoltaic cell, light incident on the secondary lens can be efficiently concentrated, and also, the excessive concentration of light can be prevented. It is thus possible to enhance the power generation efficiency of the photovoltaic cell and to improve the electrical characteristics.

The concentrating photovoltaic power generation module of the present invention is formed by combining a plurality of the concentrating photovoltaic power generation apparatuses of the present invention. A plurality of the concentrating lenses are disposed on a single light-transmitting substrate and a plurality of the photovoltaic cells are disposed on a single holding plate.

Accordingly, in the concentrating photovoltaic power generation module of the present invention, by uniformly performing each of positioning of the concentrating lenses and positioning of the photovoltaic cells, the concentrating photovoltaic power generation module in which the concentrating lenses and the photovoltaic cells are highly precisely positioned can be easily manufactured. As a result, the productivity is improved, thereby reducing the manufacturing cost, and also, the electrical characteristics are improved.

### BRIEF DESCRIPTION OF DRAWINGS

FIG. 1A is a plan view schematically illustrating a concentrating photovoltaic power generation module of the present invention, as viewed from a plane of incidence of solar radiation.

FIG. 1B is a sectional view taken along line 1B-1B of FIG. 1A.

FIG. 2A is a side view of the configuration of a secondary lens of a first embodiment.

FIG. 2B is a perspective view of the configuration of the secondary lens of the first embodiment.

FIG. 3A is a view illustrating a light-concentration path of solar radiation which is incident on the secondary lens 10A after being concentrated by a concentrating lens.

FIG. 3B is a view illustrating, as a comparative example, a light-concentration path of solar radiation in a case in which a secondary lens is formed in a generally simple hemispherical shape (dome-like shape).

FIG. 4A is a diagram three-dimensionally illustrating a light intensity distribution on the surface of a photovoltaic cell.

FIG. 4B is a diagram three-dimensionally illustrating a light intensity distribution on the surface of a photovoltaic cell.

FIG. 5A is a view illustrating a light-concentration path when light of a short wavelength range corresponding to a top cell is incident on a secondary lens.

FIG. 5B is a view illustrating a light-concentration path when light of a medium wavelength range corresponding to a middle cell is incident on the secondary lens.

FIG. 6 is a table indicating simulation results of the light-concentration efficiency when a distance D1 is set to be half or more of a distance D2 and those when the distance D1 is set to be half or less of the distance D2.

FIG. 7A is a perspective view of the configuration of a secondary lens of a second embodiment.

FIG. 7B is a plan view of the configuration of the secondary lens of the second embodiment.

FIG. 7C is a side view of the configuration of the secondary lens of the second embodiment, as viewed from the direction of an arrow X1.

FIG. 7D is a side view of the configuration of the secondary lens of the second embodiment, as viewed from the direction of an arrow X2.

FIG. 8A is a view illustrating a traveling direction of solar radiation incident on a second optical refractive face of the secondary lens of the first embodiment.

FIG. 8B is a view illustrating a traveling direction of solar radiation incident on a second optical refractive face of the secondary lens of the second embodiment.

FIG. 9A is a plan view of a concentrating photovoltaic power generation apparatus and a concentrating photovoltaic power generation module according to a third embodiment of the present invention, as viewed from concentrating lenses.

FIG. 9B is a sectional view of the concentrating photovoltaic power generation apparatus and the concentrating photovoltaic power generation module shown in FIG. 9A, taken along line 9B-9B indicated by the arrows in FIG. 9A.

FIG. 10A is a sectional view of one concentrating lens extracted from a cross section taken along line 9B-9B indicated by the arrows in FIG. 9A.

FIG. 10B is a sectional view of the concentrating lens shown in FIG. 9A, taken along line 10B-10B indicated by the arrows in FIG. 10A.

FIG. 11A is a sectional view of a concentrating lens having a configuration different from that of the concentrating lens shown in FIG. 10A, in a plane including a vertical axis.

FIG. 11B is a sectional view of the concentrating lens shown in FIG. 11A taken along line 11B-11B indicated by the arrows in FIG. 11A.

FIG. 12A is a perspective view of the configuration of a secondary lens of the third embodiment, as viewed from an obliquely upward direction.

FIG. 12B is a side view of the secondary lens shown in FIG. 12A, as viewed from a side.

FIG. 12C is a conceptual view illustrating a state in which light concentrated by a concentrating lens is concentrated and refracted when it is incident on a secondary lens, as viewed from a lateral side.

FIG. 12D is a conceptual view illustrating a state in which light concentrated by a concentrating lens is concentrated and refracted when it is incident on a secondary lens, as viewed from the direction of the vertical axis.

FIG. 13 is a conceptual view illustrating a state in which light concentrated by a concentrating lens is concentrated and refracted when it is incident on a comparative secondary lens, which is a subject to be compared with a secondary lens, as viewed from a lateral side.

FIG. 14A is a light-intensity distribution diagram which three-dimensionally illustrates an in-plane light intensity distribution on a photovoltaic cell with the use of the comparative secondary lens.

FIG. 14B is a light-intensity distribution diagram which three-dimensionally illustrates an in-plane light intensity distribution on a photovoltaic cell with the use of the secondary lens of the third embodiment.

FIG. 15A is a perspective view of the configuration of a secondary lens of a fourth embodiment, as viewed from an obliquely upward direction.

FIG. 15B is a side view of the secondary lens shown in FIG. 15A, as viewed from a side.

FIG. 15C is a plan view of the secondary lens shown in FIG. 15A, as viewed from above.

FIG. 15D is a conceptual view illustrating a state in which light concentrated by a concentrating lens is concentrated and refracted when it is incident on the secondary lens, as viewed from a lateral side.

FIG. 15E is a conceptual view illustrating a state in which light concentrated by a concentrating lens is concentrated and refracted when it is incident on the secondary lens at a position of line 15E-15E indicated by the arrows in FIG. 15B, as viewed from the direction of the vertical axis.

FIG. 15F is a conceptual view illustrating a state in which light concentrated by a concentrating lens is concentrated and refracted when it is incident on the secondary lens at a position of line 15F-15F indicated by the arrows in FIG. 15B, as viewed from the direction of the vertical axis.

FIG. 16A is a perspective view of the configuration of a comparative secondary lens, as viewed from an obliquely upward direction.

FIG. 16B is a side view of the comparative secondary lens, as viewed from a side.

FIG. 16C is a sectional view of the comparative secondary lens at a position of line 16C-16C indicated by the arrows in FIG. 16B.

FIG. 17A is a perspective view of the configuration of a secondary lens of a fifth embodiment, as viewed from an obliquely upward direction.

FIG. 17B is a side view of the secondary lens shown in FIG. 17A, as viewed from a side.

FIG. 17C is a sectional view of an outer peripheral configuration of the secondary lens at a position of line 17C-17C indicated by the arrows in FIG. 17A.

FIG. 18A is a plan view of a concentrating photovoltaic power generation apparatus and a concentrating photovoltaic power generation module, which serve as a first example of the related art, as viewed from concentrating lenses.

FIG. 18B is a sectional view of the concentrating photovoltaic power generation apparatus and the concentrating photovoltaic power generation module shown in FIG. 18A, taken along line 18B-18B indicated by the arrows in FIG. 18A.

FIG. 19A is a plan view of a concentrating photovoltaic power generation apparatus and a concentrating photovoltaic power generation module, which serve as a second example of the related art, as viewed from concentrating lenses.

FIG. 19B is a schematic view illustrating a state in which light is concentrated, by enlarging secondary glass used in the concentrating photovoltaic power generation apparatus and the concentrating photovoltaic power generation module shown in FIG. 19A.

### DESCRIPTION OF EMBODIMENTS

Embodiments of the present invention will be described below with reference to the drawings.

### First Embodiment

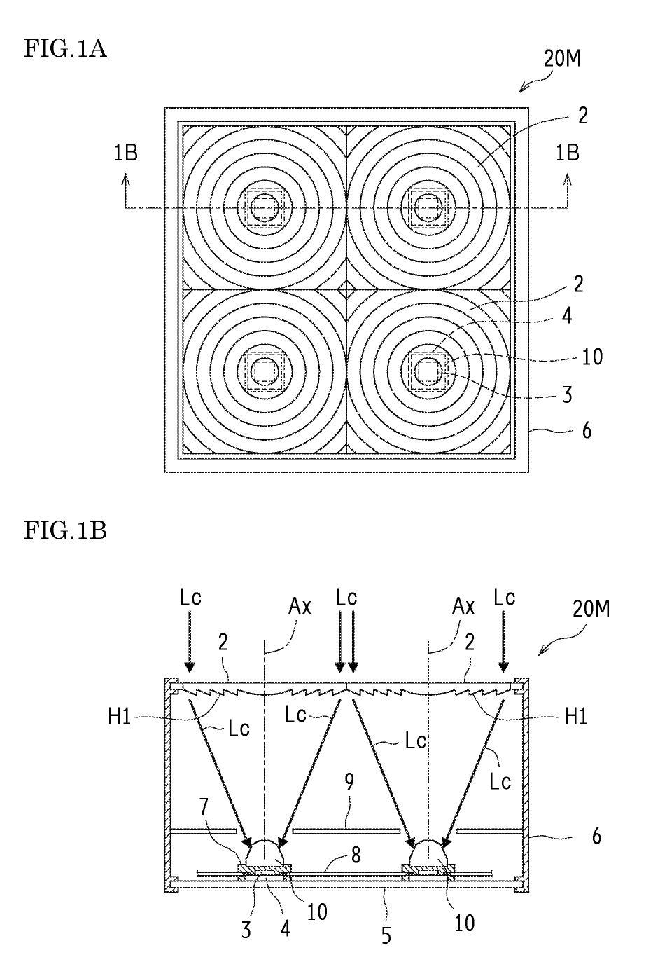

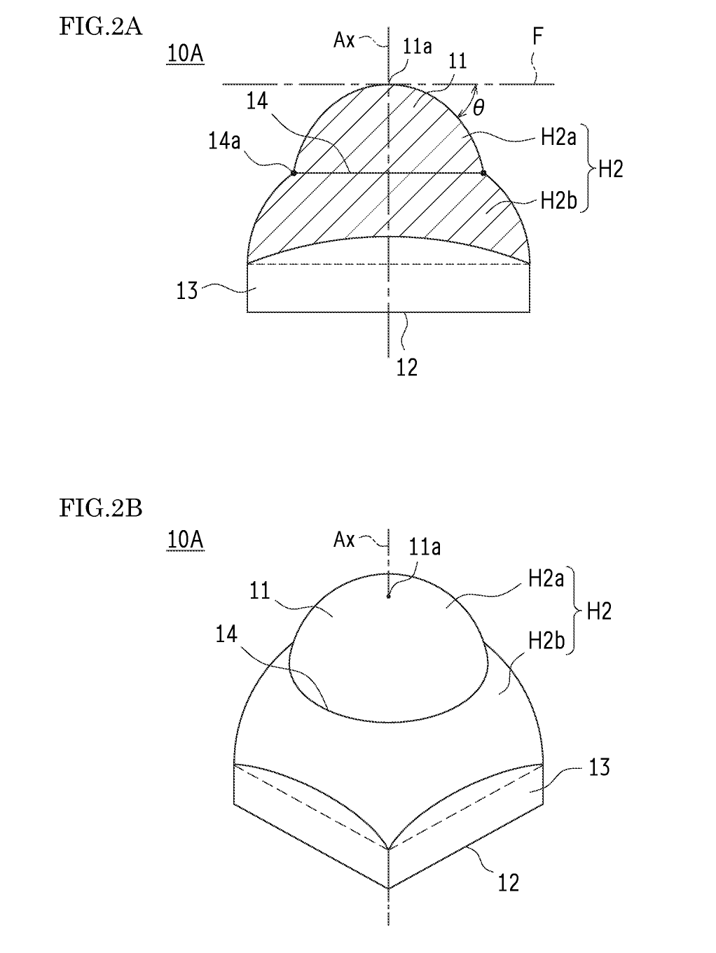

FIGS. 1A and 1B are schematic views illustrating the configuration of a concentrating photovoltaic power generation module of the present invention. FIG. 1A is a plan view of the concentrating photovoltaic power generation module, as viewed from a plane of incidence of solar radiation Lc. FIG. 1B is a sectional view taken along line 1B-1B of FIG. 1A. FIGS. 2A and 2B illustrate the configuration of a secondary lens of a first embodiment. FIG. 2A is a side view of the secondary lens, and FIG. 2B is a perspective view of the secondary lens. The hatched portion of FIG. 2A indicates an optical refractive face of a light incoming section, which will be discussed later.

A concentrating photovoltaic power generation module 20M is constituted by a plurality of sets of concentrating photovoltaic power generation units (hereinafter may be simply referred to as a “unit”), each unit including a concentrating lens 2, which is a primary optical system, a secondary lens 10A of the first embodiment, which is a secondary optical system, and a photovoltaic cell 3. A suitable number of photovoltaic cells are electrically connected to each other so as to obtain a required current and a required voltage. Each unit has a size of several tens of millimeters to several hundreds of millimeters.

The photovoltaic cell 3 is mounted on a receiver substrate 4. A holding plate 5 holds the receiver substrates 4 and opposes the concentrating lenses 2. A module frame 6 holds the concentrating lenses 2 and the holding plate 5 such that each photovoltaic cell 3 is positioned on an optical axis Ax of the concentrating lens 2 (that is, the optical axis of the optical system in a direction perpendicular to the concentrating lenses 2, which serve as a light receiving surface of the concentrating photovoltaic power generation module 20M).

The secondary lens 10A is mounted on the upper surface at the center of the photovoltaic cell 3, and refracts the solar radiation Lc concentrated by the concentrating lens 2 and applies it to the photovoltaic cell 3.

A light-transmitting filler 7 is filled between the photovoltaic cell 3 and the secondary lens 10A, and forms a filling portion that fixes the photovoltaic cell 3, the receiver substrate 4, and the secondary lens 10A to each other. That is, the secondary lens 10A, the photovoltaic cell 3, the receiver substrate 4, and the light-transmitting filler 7 form a photovoltaic cell mounting body.

An output cable 8 is used for extracting an output of the photovoltaic cell 3.

A light-shielding sheet 9 is used for blocking the solar radiation (concentrated light beam) Lc concentrated by the concentrating lens 2 so as to prevent the solar radiation Lc from being applied to unnecessary locations, such as the output cable 8 and the receiver substrate 4.

The solar radiation Lc is incident from a direction parallel with the optical axis Ax and is refracted by the concentrating lens 2, and then, it is concentrated toward the photovoltaic cell 3.

In the concentrating lens 2, the surface on which the solar radiation Lc is refracted so as to be concentrated toward the optical axis Ax serves as an optical refractive face H1. In this embodiment, the concentrating lens 2 is formed as a concentric Fresnel lens, from the viewpoint of making the concentrating lens 2 thinner and lighter and reducing the material cost and also improving the light-concentrating power factor and the molding workability. The concentrating lens 2 is formed into a quadrilateral shape, and then, four concentrating lenses 2 are arranged in rows and columns and are held by the module frame 6.

As a material for the concentrating lens 2, for example, a silicone resin is used. However, various light-transmitting materials may be used as a material for the concentrating lens 2, and, specifically, an acrylic resin, such as PMMA (polymethyl methacrylate resin), polycarbonate, or glass may be used.

As the photovoltaic cell 3, an inorganic photovoltaic cell formed from Si, GaAs, CuInGaSe, CdTe, or the like, an organic photovoltaic cell, such as a dye-sensitized solar cell, is used. The photovoltaic cell may be of a single-junction cell type, a monolithic multi-junction cell type, or a mechanically stacked cell type in which various photovoltaic cells having different sensitivity ranges are stacked on each other. However, since high efficiency is particularly demanded for a concentrating photovoltaic power generation module, the use of a multi-junction photovoltaic cell (for example, InGaP/GaAs/Ge3 triple-junction photovoltaic cell) or a mechanically stacked cell is preferable. In this embodiment, a triple-junction photovoltaic cell is used. It is necessary to reduce the external dimensions of the photovoltaic cell 3 to as small as possible, in terms of a decrease in the materials used for the photovoltaic cell, which is one of the objects to be achieved by the concentrated power generation module. Thus, the photovoltaic cell 3 of about several millimeters to 20 mm is used.

The secondary lens 10A includes a light incoming section 11 and a light outgoing section 12 (see FIG. 2A). The light incoming section 11 opposes the concentrating lens 2 and has a first face on which a light beam concentrated by the concentrating lens 2 is incident as incident light. The light outgoing section 12 opposes the photovoltaic cell 3 and has a second face from which the concentrated light beam incident from the concentrating lens 2 is output. The secondary lens 10A outputs the light incident on the light incoming section 11 from the light outgoing section 12 and then guides the light to the photovoltaic cell 3. The surface of the light incoming section 11 on which the light is incident is an optical refractive face H2 (see FIG. 2A). As stated above, the secondary lens 10A is bonded and fixed to the upper surface of the photovoltaic cell 3 with the light-transmitting filler 7 therebetween, integrally with the photovoltaic cell 3 and the receiver substrate 4.

An intermediate region 13, which does not optically contribute, is provided between the light incoming section 11 and the light outgoing section 12 of the secondary lens 10A. Because of the provision of the intermediate region 13, when bonding and fixing the secondary lens 10A to the photovoltaic cell 3 and the receiver substrate 4, even if the light-transmitting filler 7 adheres to a lateral surface of the secondary lens 10A, that is, to the intermediate region 13, the output characteristics of the photovoltaic cell 3 are not influenced at all. Likewise, if a jig or another suitable member is used for precisely adjusting the position of the secondary lens 10A to the position of the photovoltaic cell 3 or the optical axis Ax (though a specific structure of such a jig or member is not described here), it may be safely abutted against the intermediate region 13. Accordingly, the manufacturing process for the concentrating photovoltaic power generation module can be simplified, thereby making it possible to more reliably and inexpensively perform the assembly of the concentrating photovoltaic power generation module.

As a material for the secondary lens 10A, a material exhibiting a high light transmittance in a wavelength range corresponding to the sensitivity of the photovoltaic cell 3 and having resistance to weather is preferable, and, for example, glass, an acrylic resin, or polycarbonate may be used. However, the material for the secondary lens 10A is not restricted to one of these materials, and a multilayer of these materials may be used. Additionally, a suitable ultraviolet absorber may be added to these materials, for the purpose of suppressing UV degradation of materials within the concentrating photovoltaic power generation module or UV degradation of the secondary lens 10A. A suitable antireflection coat may also be disposed, for the purpose of decreasing the optical reflectance in the wavelength range corresponding to the sensitivity of the photovoltaic cell 3. Accordingly, reflection loss on the surface of the secondary lens 10A can be reduced, thereby making it possible to increase the output of the photovoltaic cell 3. If it is possible to sufficiently reduce surface reflection by the provision of an antireflection coat, a material having a high refractive index may be used for the secondary lens 10A. It is also possible to provide a film, such as a UV reflection film or an infrared reflection film, which reflects light of a wavelength other than the wavelength range corresponding to the sensitivity of the photovoltaic cell 3.

The secondary lens 10A of the first embodiment will be discussed in a greater detail below with reference to FIGS. 2A and 2B.

The configuration of the secondary lens 10A of the first embodiment is as follows. The cross-sectional area of the secondary lens 10A in a direction perpendicular to the optical axis Ax of the light incoming section 11 monotonically increases as it approaches from a side of the secondary lens 10A closer to the concentrating lens 2 (upper side in FIGS. 2A and 2B) toward a side of the concentrating lens 10A closer to the photovoltaic cell 3 (lower side in FIGS. 2A and 2B). The angle of inclination θ of the optical refractive face H2 of the light incoming section 11 to a face F in a direction perpendicular to the optical axis Ax monotonically increases as it approaches from the side closer to the concentrating lens 2 toward the side closer to the photovoltaic cell 3. At least one point of inflection 14a at which the angle of inclination θ starts to decrease (become gentle) while the angle of inclination θ monotonically is increasing (that is, a line of inflection 14 passing through the point of inflection 14a, as viewed from above in a direction of the optical axis Ax) is provided. In the first embodiment, one point of inflection 14a (one line of inflection 14) is provided. That is, in the first embodiment, the light incoming section 11 has a configuration in which two generally hemispherical portions are vertically overlaid on each other (or a generally hemispherical portion is squeezed toward the inner side in a half way through in the height direction by providing one step portion). In the following description, the optical refractive face of the light incoming section 11 higher than the line of inflection 14 (the side closer to the concentrating lens 2) will be referred to as a “first optical refractive face H2a”, and the optical refractive face of the light incoming section 11 below the line of inflection 14 (the side closer to the photovoltaic cell 3) will be referred to as a “second optical refractive face H2b”.

With this configuration, the cross-sectional configurations of the first and second optical refractive faces H2a and H2b in a direction perpendicular to the optical axis Ax are made circular, and thus, they are similar to the cross-sectional configuration of the concentrating lens 2 in a direction perpendicular to the optical axis Ax.

In this manner, by forming the cross-sectional configurations of the first and second optical refractive faces H2a and H2b in a direction perpendicular to the optical axis Ax to be similar to the cross-sectional configuration of the optical refractive face H1 of the concentrating lens 2 in a direction perpendicular to the optical axis Ax, the light-concentration efficiency on the surface of the photovoltaic cell 3 can be improved.

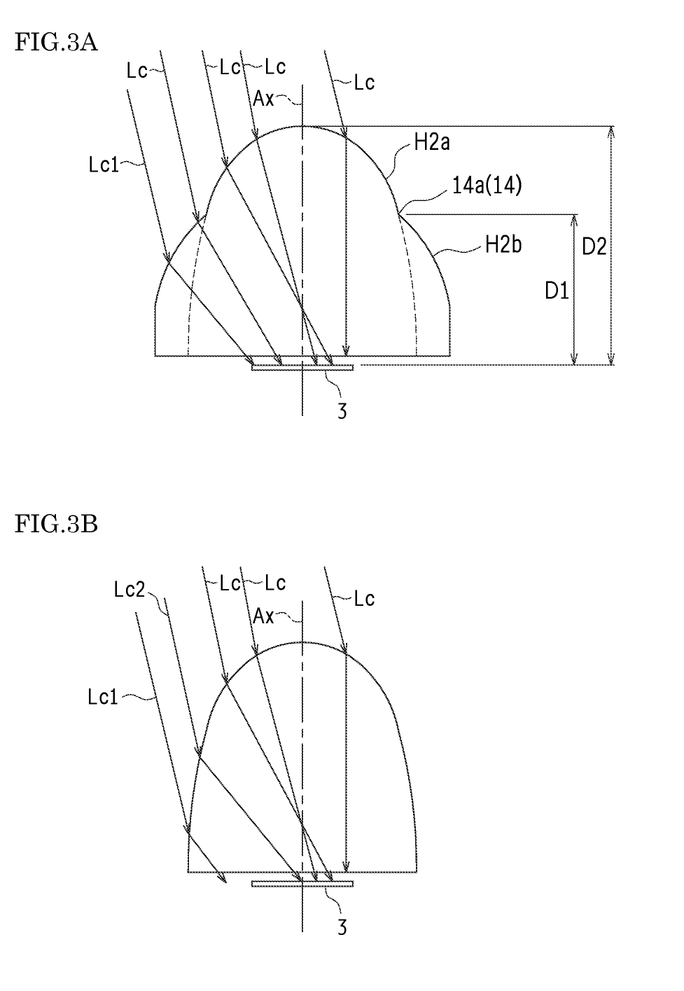

FIG. 3A is a view illustrating a light-concentration path of solar radiation Lc which is incident on the secondary lens 10A after being concentrated by the concentrating lens 2. FIG. 3B illustrates, for comparison, a light-concentration path of solar radiation Lc in a case in which a secondary lens is formed in a generally simple hemispherical shape (dome-like shape) (hereinafter such a lens will be referred to as a “secondary lens of a comparative example”).

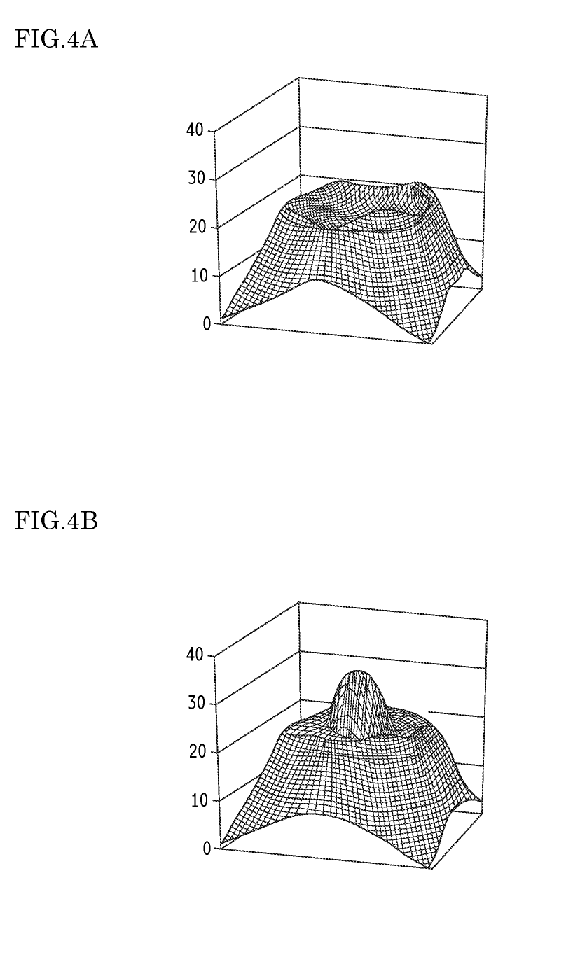

In the secondary lens 10A of the first embodiment, as shown in FIG. 3A, the solar radiation Lc incident on the first optical refractive face H2a almost entirely reaches the surface of the photovoltaic cell 3. The solar radiation Lc incident on the second optical refractive face H2b reaches the photovoltaic cell 3 in the following manner. Since the optical refractive face tilts gently near the line of inflection 14, the solar radiation Lc1 incident on comparatively an outer portion of the second optical refractive face H2b is incident on the secondary lens 10A at a relatively high position (closer to the concentrating lens 2) of the secondary lens 10A, compared with a case in which the secondary lens 10A would not have a point of inflection. Accordingly, the solar radiation Lc1 reaches an end portion of the photovoltaic cell 3. As a result, as shown in FIG. 4A which three-dimensionally indicates an in-plane light intensity distribution on the photovoltaic cell 3 (cell surface), the solar radiation Lc substantially uniformly reaches the in-plane surface of the photovoltaic cell 3 without being excessively concentrated. In this example, the maximum intensity value in the light intensity distribution when the secondary lens 10 of the first embodiment is used only slightly exceeds 20.

In contrast, in the secondary lens of the comparative example, as shown in FIG. 3B, the solar radiation Lc1 incident on a lower portion of the lens, which corresponds to the second optical refractive face H2b of the first embodiment, does not reach the photovoltaic cell 3, since a sufficient length of the optical path is not secured due to a shortage of the height of the plane of incidence. Meanwhile, because of the absence of the line of inflection 14, the solar radiation Lc2 incident on the lens face, which corresponds to a portion below and near the line of inflection 14, is likely to be directed toward the center of the optical axis. As a result, as shown in FIG. 4B which three-dimensionally indicates an in-plane light intensity distribution on the photovoltaic cell 3, the level of the solar radiation Lc which has reached the surface of the photovoltaic cell 3 in the light intensity distribution is high at the center portion of the photovoltaic cell 3. In this example, the maximum intensity value in the light intensity distribution when the secondary lens of the comparative example is used slightly exceeds 30. The above-described phenomenon is more noticeable when a multi-junction cell (for example, a triple-junction cell) is used as the photovoltaic cell 3 and when light of a medium wavelength range to a long wavelength range is concentrated on the photovoltaic cell 3. That is, it is seen that, by the use of the secondary lens 10A of the first embodiment, it is possible to reduce the maximum intensity value in the in-plane light intensity distribution on the photovoltaic cell 3 to about two thirds of that when the secondary lens of the comparative lens is used, and it is also possible to substantially uniformly distribute the solar radiation Lc on the surface of the photovoltaic cell 3.

That is, in the first embodiment, by forming the entirety of the secondary lens 10A in a dome-like shape and then by providing a step portion (point of inflection 14a) where the gradient of the optical refractive face starts to become gentle in a half way through in the height direction of this dome-like shape, the concentration of light on the surface of the photovoltaic cell 3 can be decreased (distributed), thereby making it possible to uniformly apply light to the surface of the photovoltaic cell 3. That is, by using the secondary lens 10A of the present invention for the concentrating photovoltaic power generation module 20M, the power generation efficiency (conversion efficiency) of the photovoltaic cell 3 can be improved.

In the secondary lens 10A of the first embodiment, it is desirable that the line of inflection 14 passing through the point of inflection 14a be positioned on the outside of the photovoltaic cell 3 which opposes the secondary lens 10A, as viewed from above in a direction of the optical axis.

By positioning the line of inflection 14 passing through the point of inflection 14a on the outside of the photovoltaic cell 3 as viewed from above, the solar radiation Lc1 incident on a relatively outer portion of the second optical refractive face H2b reaches an end portion of the surface of the photovoltaic cell 3, as stated above. It is thus possible to uniformly apply light to the surface of the photovoltaic cell 3.

In the secondary lens 10A of the first embodiment, a cross-sectional configuration of the first optical refractive face H2a, which is a region from a vertex portion 11a of the secondary lens to the point of inflection 14a (line of inflection 14), in a direction perpendicular to the optical axis is set to be similar to that of the optical refractive face H1 of the concentrating lens 2 in a direction perpendicular to the optical axis. That is, in this embodiment, since the concentrating lens 2 is formed as a concentric Fresnel lens, the cross-sectional configuration of the optical refractive face H1 of the concentrating lens 2 in a direction perpendicular to the optical axis is circular, and the cross-sectional configuration of the first optical refractive face H2a of the secondary lens 10A in a direction perpendicular to the optical axis is also formed circular.

In this manner, by forming the cross-sectional configuration of the first optical refractive face H2a in a direction perpendicular to the optical axis Ax to be similar to that of the optical refractive face H1 of the concentrating lens 2 in a direction perpendicular to the optical axis Ax, the solar radiation Lc output from the concentrating lens 2 is concentrated toward the optical axis Ax (that is, on the surface of the photovoltaic cell 3). On the other hand, by providing the point of inflection 14a (line of inflection 14) where the gradient of the optical refractive face H2 starts to become gentle, it is possible to decrease the concentration of the solar radiation Lc on the surface of the photovoltaic cell 3 (that is, the light is first concentrated, and then, it is dispersed by being displaced in the radial direction from the center of the optical axis on the surface of the photovoltaic cell 3). That is, by the concentration and the dispersion of light, it is possible to uniformly apply a possibly large amount of solar radiation Lc to the surface of the photovoltaic cell 3, thereby improving the power generation efficiency (conversion efficiency) of the photovoltaic cell 3.

In this embodiment, as the photovoltaic cell 3, a triple-junction photovoltaic cell (for example, a triple-junction photovoltaic cell constituted by InGaP (top cell)/GaAs (middle cell)/Ge (bottom cell)) is used. In this case, the position at which the point of inflection 14a (line of inflection 14) is formed is set such that light of a wavelength range corresponding to the photovoltaic cell (the top cell of the triple-junction photovoltaic cell) having sensitivity to a short wavelength is not incident on the second optical refractive face H2b. In this case, the term “such that light of a wavelength range corresponding to the top cell is not incident on the second optical refractive face H2b” means that, in terms of design, light of this wavelength range is not incident on the second optical refractive face H2b. Depending on the actual operating environment, however, a small amount of light may be incident on the second optical refractive face H2b due to, for example, a change in the ambient temperature or manufacturing errors. However, such an amount of incident light may be safely negligible. That is, in terms of design, the point of inflection 14a (line of inflection 14) is formed at a position outside a range in which light of a short wavelength range is incident. With this configuration, light of a wavelength range corresponding to the top cell is incident on the first optical refractive face H2a, but is not incident (strictly speaking, it is hardly incident) on the second optical refractive face H2b. Thus, the light of a wavelength range to be incident on the surface of the top cell is efficiently concentrated, and then, it is applied to the top cell.

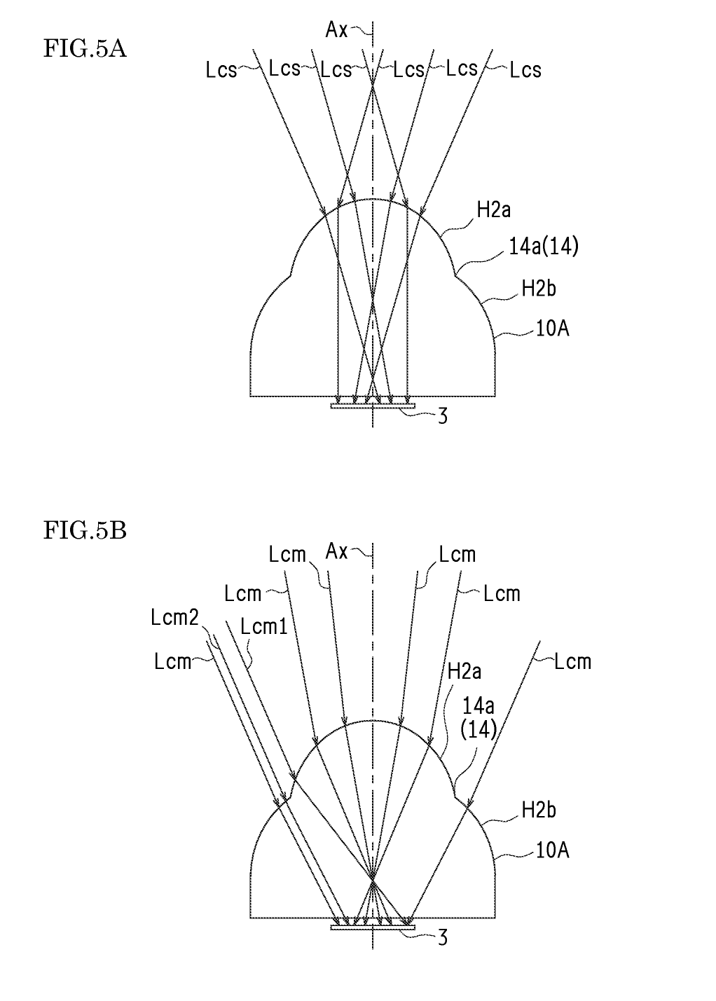

FIG. 5A illustrates a light-concentration path when light Lcs of a short wavelength range corresponding to the top cell is incident on the secondary lens 10A.

The light Lcs of a short wavelength range corresponding to the top cell has a great degree of dispersion and is thus applied to a large area. It is thus necessary to concentrate the light Lcs by aiming at the center of the secondary lens 10A in order to maintain the light-concentration efficiency (optical efficiency). In this case, if, as shown in FIG. 5A, a concentrated light beam is contained within a certain range around the optical axis Ax, it is possible to decrease the concentration of the light Lcs of a short wavelength to be incident on the surface of the top cell and to uniformly apply the light Lcs to the surface of the top cell. As a result, the light-concentration efficiency (conversion efficiency) of the light Lcs of a short wavelength corresponding to the top cell is improved.

In the secondary lens 10A of the first embodiment, the angles of inclination of the first and second optical refractive faces H2a and H2b and the position of the point of inflection 14a (line of inflection 14) in the height direction of the secondary lens 10A are set such that light of a specific wavelength incident on a portion of the first optical refractive face H2a above and near the point of inflection 14a (line of inflection 14) (near the boundary with the point of inflection 14a) reaches the photovoltaic cell 3 after crossing the optical axis Ax and such that light of a specific wavelength incident on a portion of the second optical refractive face H2b below and near the point of inflection 14a (line of inflection 14) (near the boundary with the point of inflection 14a) reaches the photovoltaic cell 3 before crossing the optical axis Ax.

The specific wavelength may be set to be, for example, a medium wavelength of 650 to 900 nm corresponding to the middle cell.

FIG. 5B illustrates a light-concentration path when light Lcm of a medium wavelength range corresponding to the middle cell is incident on the secondary lens 10A.

As shown in FIG. 5B, the light Lcm of a medium wavelength range is applied to a relatively small range. Additionally, since the angle of refraction of the light Lcm at the concentrating lens 2 is smaller than that of light of a short wavelength range, the light Lcm is concentrated in an outer portion than the light of a short wavelength range. Accordingly, by providing the point of inflection 14a (line of inflection 14), the gradient of the optical refractive face positioned on the outside of the line of inflection 14 (that is, the second optical refractive face H2b) is made gentle. Then, the light Lcm of a medium wavelength range incident on the surface of the secondary lens 10A far away from the optical axis Ax of the secondary lens 10A can be efficiently concentrated on the surface of the middle cell. In this case, the light Lcm of a medium wavelength range is distributed such that light (light Lcm1) incident on a portion above the point of inflection 14a (line of inflection 14) advances in a direction in which it crosses the optical axis Ax and such that light (light Lcm2) incident on a portion below the point of inflection 14a (line of inflection 14) advances in a direction in which it does not cross the optical axis Ax. Thus, the light of a medium wavelength range is uniformly applied to the surface of the middle cell, thereby making it possible to increase the conversion efficiency (output voltage) of the middle cell.

In the secondary lens 10A of the first embodiment, a distance D1 from the point of inflection 14a (line of inflection 14) to the photovoltaic cell 3 is set to be half or more of a distance D2 from the vertex of the secondary lens 10A to the surface of the photovoltaic cell 3.

In this manner, by setting the distance D1 from the point of inflection 14a to the surface of the photovoltaic cell to be half or more of the distance D2 from the vertex of the secondary lens 10A to the surface of the photovoltaic cell 3, the point of inflection 14a (line of inflection 14) can be provided at the upper side (closer to the vertex side) where the light-concentration efficiency is decreased.

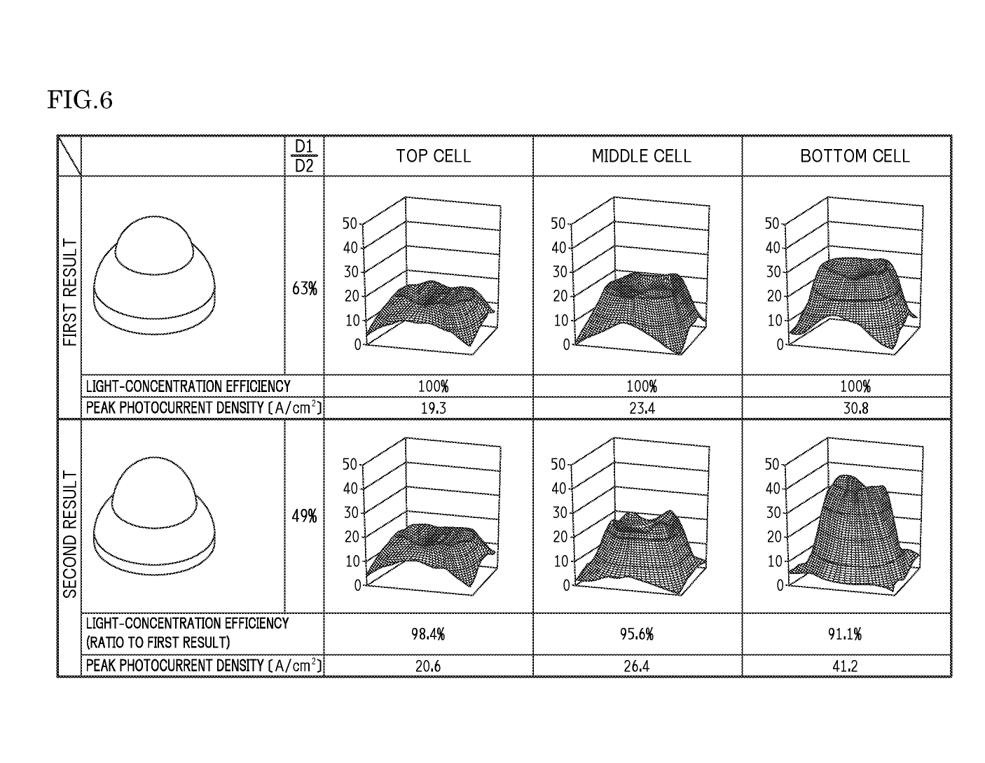

FIG. 6 is a table indicating simulation results of the light-concentration efficiency when the distance D1 is set to be half or more of the distance D2 and those when the distance D1 is set to be half or less of the distance D2.

A first result is simulation results obtained when the distance D1 is set to be half or more of the distance D2 (in this example, the distance D1 is 63% of the distance D2), and a second result is simulation results obtained when the distance D1 is set to be half or less of the distance D2 (in this example, the distance D1 is 49% of the distance D2).

In these simulations, the lens size of the concentrating lens 2 is 170 mm square, the height of the secondary lens 10A is 11.4 mm, the diameter of the light outgoing section 12 of the secondary lens 10A is 14.4 mmφ, and the size of the photovoltaic cell is 4.5 mm square.

The first result shows that the light is substantially uniformly distributed on the surface of the top cell with a light intensity distribution of about 20, that the light is substantially uniformly distributed on the surface of the middle cell with a light intensity distribution of about 25, and that the light is substantially uniformly distributed on the surface of the bottom cell with a light intensity distribution of about 30.

In contrast, the second result shows that, although the light is substantially uniformly distributed on the surface of the top cell with a light intensity distribution of about 20, the light is less uniformly distributed on the surface of the middle cell with a light intensity distribution of about 25 than that of the first result, and also, the light tends to be slightly excessively concentrated on the center of the middle cell, and that the light is less uniformly distributed on the surface of the bottom cell with a light intensity distribution of about 40 than that of the first result, and also, the light tends to be excessively concentrated on the center of the bottom cell.

As a result, in the second result, the light-concentration efficiency in the top cell is slightly reduced to 98.4% compared with the first result, the light-concentration efficiency in the middle cell is further reduced to 95.6% compared with the first result, and the light-concentration efficiency in the bottom cell is even further reduced to 91.1% compared with the first result (these ratios of the light-concentration efficiency are indicated, assuming that the light-concentration efficiency of the first result is considered to be 100%). In other words, the light-concentration efficiency of the secondary lens of the first result is increased in all the cells, compared with the secondary lens of the second result. In view of the actual state of the use of the secondary lens, even with the light-concentration efficiency of the second result, the advantages of the secondary lens of the invention of this application are obtained on a practical basis.

These results show that a sufficient level of improvement in the light-concentration efficiency on a practical basis is observed by setting the distance D1 to be half or more of the distance D2. That is, the position of the point of inflection 14a (line of inflection 14) in the height direction formed in the secondary lens 10A may be set such that the distance D1 from the point of inflection 14a to the surface of the photovoltaic cell 3 is half or more of the distance D2 from the vertex of the secondary lens 10A to the surface of the photovoltaic cell 3.

### Second Embodiment

A second embodiment of a secondary lens will be described below.

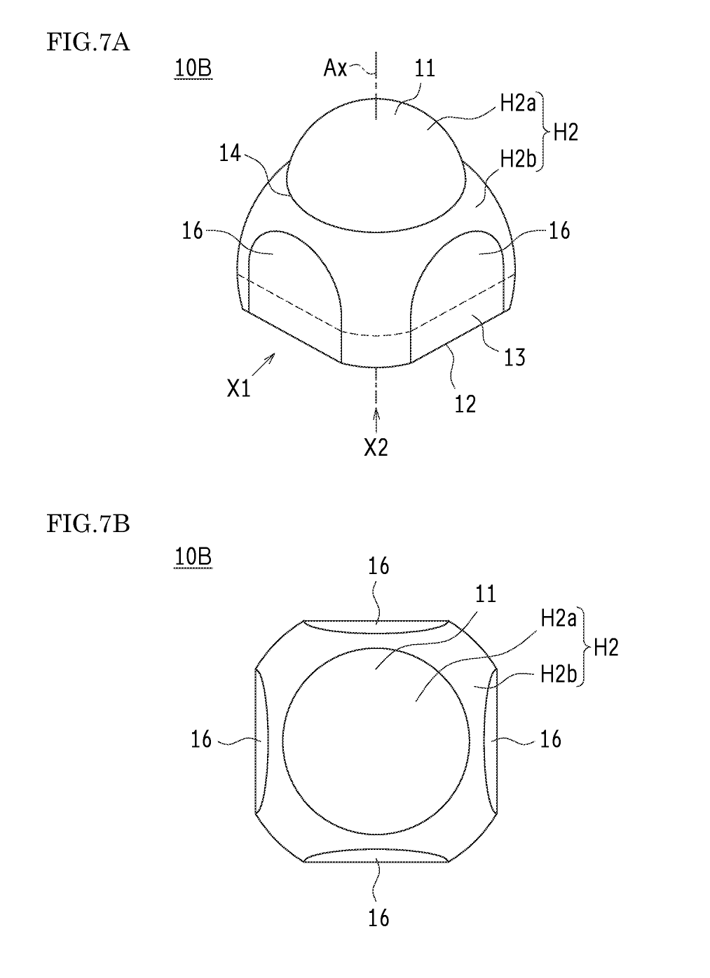

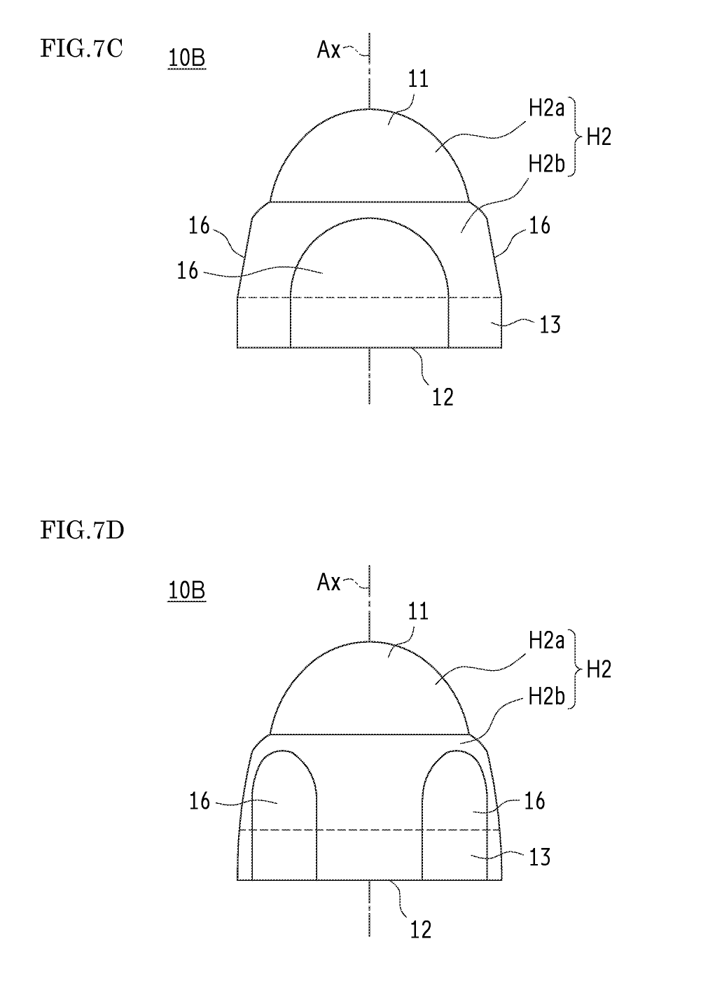

FIGS. 7A through 7D illustrate the configuration of a secondary lens 10B of the second embodiment: FIG. 7A is a perspective view of the secondary lens 10B; FIG. 7B is a plan view of the secondary lens 10B; FIG. 7C is a side view of the secondary lens 10B, as viewed from the direction of the arrow X1 in FIG. 7A; and FIG. 7D is a side view of the secondary lens 10B, as viewed from the direction of the arrow X2 in FIG. 7A.

The secondary lens 10B of the second embodiment is different from the secondary lens 10A of the first embodiment in that chamfered portions 16 are formed at four locations around the second optical refractive face H2b. Accordingly, in the secondary lens 10B of the second embodiment, the cross-sectional configuration of the second optical refractive face H2b of the secondary lens 10B in a direction perpendicular to the optical axis is not similar to that of the optical refractive face H1 of the concentrating lens 2 in a direction perpendicular to the optical axis. That is, in this embodiment, since the concentrating lens 2 is formed as a concentric Fresnel lens, the cross-sectional configuration of the optical refractive face H1 of the concentrating lens 2 in a direction perpendicular to the optical axis is circular. In contrast, the cross-sectional configuration of the second optical refractive face H2b of the secondary lens 10B has a polygonal shape in which segments and straight lines are sequentially repeated (generally octagonal shape) as a result of forming the chamfered portions 16 at four locations around the second optical refractive face H2b.

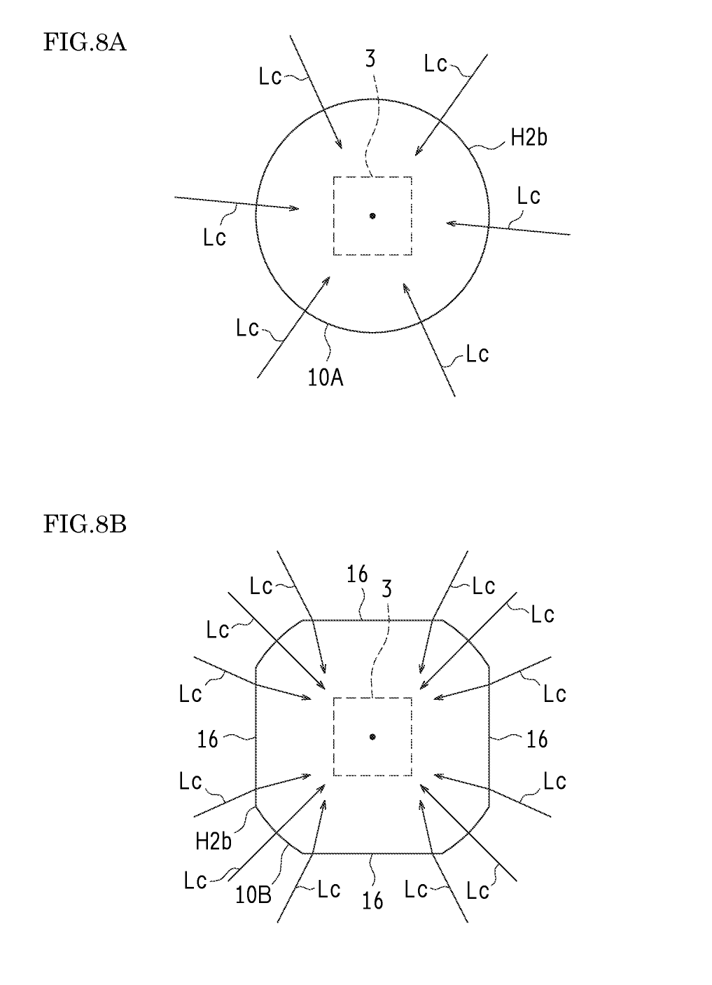

Thus, in the first embodiment, as shown in FIG. 8A, the solar radiation Lc incident on the second optical refractive face H2b advances in a straight line toward the optical center P, as viewed from above. In the second embodiment, however, as shown in FIG. 8B, the solar radiation Lc, which is incident on the chamfered portions 16, is refracted such that it separates from the optical center P, and is thus incident while being extended and dispersed around the optical center P, as viewed from above. As a result, the solar radiation Lc is also dispersed and reaches the surface of the photovoltaic cell 3.

That is, in the secondary lens 10B of the second embodiment, in addition to the above-described effect of the secondary lens 10A of the first embodiment (that is, the effect of dispersing the solar radiation Lc which will be incident on the surface of the photovoltaic cell 3 and decreasing the concentration of the solar radiation Lc on the surface of the photovoltaic cell 3 by preventing the solar radiation Lc incident on the second optical refractive face H2b from reaching the center of the photovoltaic cell 3 by the provision of the point of inflection 14a (line of inflection 14)), the effect of dispersing the solar radiation Lc which will be incident on the surface of the photovoltaic cell 3 and decreasing the concentration of the solar radiation Lc on the surface of the photovoltaic cell 3 by refracting, in the horizontal direction as viewed from above, the solar radiation Lc incident on the chamfered portions 16, which are not similar to the concentrating lens 2, is further obtained. Accordingly, due to this synergistic effect, the solar radiation Lc can be further uniformly applied to the surface of the photovoltaic cell. As a result, the power generation efficiency (conversion efficiency) of the photovoltaic cell 3 is further improved.

The cross-sectional configuration of the second optical refractive face of the secondary lens in a direction perpendicular to the optical axis is not similar to that of the optical refractive face of the concentrating lens. The configuration of such a secondary lens is not restricted to the configuration of the secondary lens 10B of the second embodiment (having chamfered portions at four locations around the second optical refractive face). The secondary lens may be formed in various shapes, by considering the balance with a cross-sectional configuration of the concentrating lens 2. For example, if the cross-sectional configuration of the optical refractive face of the concentrating lens is a quadrilateral shape, the cross-sectional configuration of the secondary lens may be a circular shape, which is similar to that of the first embodiment.

In the concentrating photovoltaic power generation module 20M of the present invention, in the photovoltaic cell mounting body, an air space between each of the secondary lenses 10A and 10B and the photovoltaic cell 3 is eliminated by filling the light-transmitting filler 7 between the secondary lens 10 and the photovoltaic cell 3. With this configuration, since the reflection of light at the interface between each of the secondary lenses 10A and 10B and an air space can be suppressed, light output from each of the secondary lenses 10A and 10B can be efficiently guided to the photovoltaic cell 3, thereby enhancing the light-concentration efficiency and further improving the power generation efficiency (conversion efficiency).

### Third Embodiment

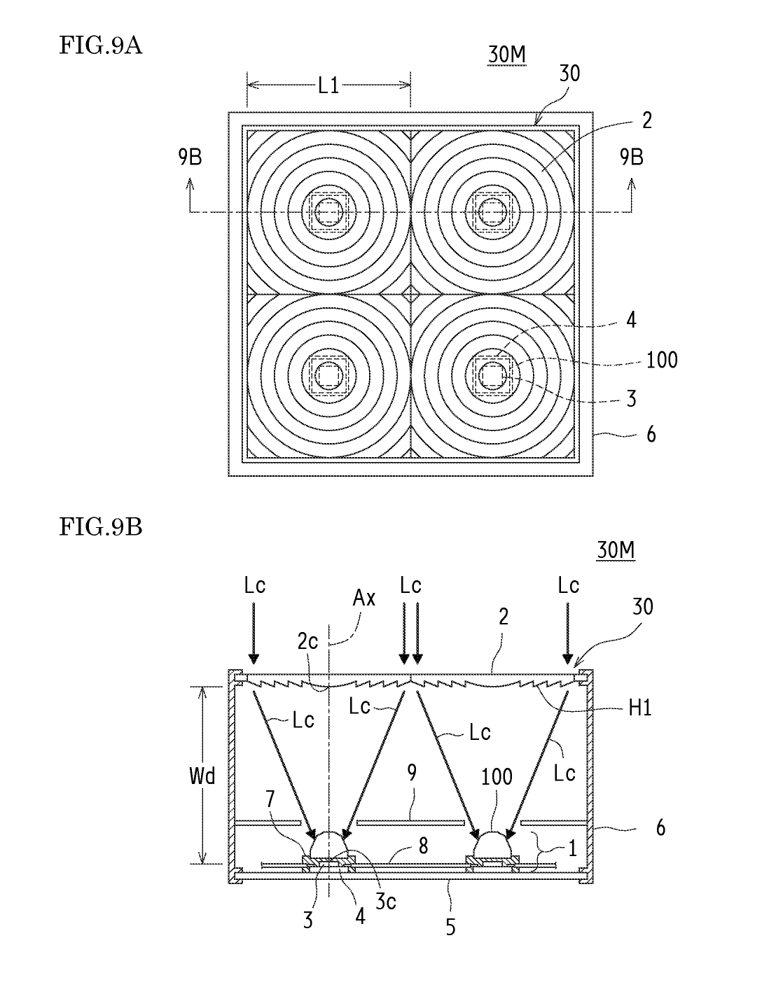

A description will be given, with reference to FIGS. 9A through 14B, a secondary lens 100, a concentrating photovoltaic power generation apparatus 30, a concentrating photovoltaic power generation module 30M, and a photovoltaic cell mounting body 1 according to a third embodiment.

FIG. 9A is a plan view of the concentrating photovoltaic power generation apparatus 30 and the concentrating photovoltaic power generation module 30M according to the third embodiment of the present invention, as viewed from the concentrating lenses 2.

FIG. 9B is a sectional view of the concentrating photovoltaic power generation apparatus 30 and the concentrating photovoltaic power generation module 30M shown in FIG. 9A, taken along line 9B-9B indicated by the arrows in FIG. 9A. For the purpose of easy representation of the drawings, the hatched portions indicating cross sections are only partially indicated.

The concentrating photovoltaic power generation apparatus 30 includes a concentrating lens 2, which is a primary lens, and a photovoltaic cell 3. A receiver substrate 4 has a photovoltaic cell 3 mounted thereon. A holding plate 5 holds the receiver substrates 4 and opposes the concentrating lenses 2. A module frame 6 interconnects the concentrating lenses 2 and the holding plate 5 so as to form a vertical axis Ax defined by a center (surface center) 2c of a concentrating lens 2 and a center (center of the light-receiving surface) 3c of a photovoltaic cell 3. The secondary lens 100 opposes the photovoltaic cell 3 and is bonded and fixed to the photovoltaic cell 3 and the receiver substrate 4 with a light-transmitting-material filling portion 7 therebetween.

That is, the secondary lens 100 is disposed opposite the photovoltaic cell 3 so that it may refract light Lc (generally and specifically, solar radiation) concentrated by the concentrating lens 2 and apply the light Lc to the photovoltaic cell 3. The secondary lens 100, the photovoltaic cell 3, the receiver substrate 4, and the light-transmitting-material filling portion 7 form the photovoltaic cell mounting body 1. The concentrating photovoltaic power generation apparatus 30 has a work distance Wd as a spacing between the concentrating lens 2 and the photovoltaic cell 3.

The light-transmitting-material filling portion 7 is made from a light-transmitting material which is filled between the photovoltaic cell 3 and the secondary lens 100, and seals the photovoltaic cell 3 between the receiver substrate 4 and the secondary lens 100. An output cable 8 is connected to the photovoltaic cell 3 and extracts an output of the photovoltaic cell 3. A light-shielding sheet 9 shields members disposed around the photovoltaic cell 3 from light so as to protect members (such as the output cable 8) which may be damaged by the irradiation of the light Lc concentrated by the concentrating lens 2.

The photovoltaic cell 3 is preferably a triple-junction compound photovoltaic cell having a high level of power generation efficiency. However, the photovoltaic cell 3 is not restricted to this type, and may be a monocrystalline or polycrystalline silicon photovoltaic cell or a multi-junction compound photovoltaic cell other than a triple-junction type.

The concentrating lens 2 has an optical refractive face H1 on which light Lc is refracted so as to be concentrated toward the secondary lens 100 disposed on the vertical axis Ax. Generally, the vertical axis Ax coincides with the optical axis of the concentrating lens 2. Accordingly, hereinafter, the vertical axis Ax and the optical axis of the concentrating lens 2 will be simply referred to as the “vertical axis Ax”.

The concentrating lens 2 is molded from, for example, a silicone resin. If the concentrating lens 2 is molded from a silicone resin, the refractive index n fluctuates in accordance with a change in the lens temperature. For example, the refractive index nD (D-line refractive index, that is, the refractive index with respect to light of a wavelength of 589 nm) is 1.412 at a temperature of 20° C., and is 1.405 at a temperature of 40° C.

If the concentrating lens 2 is an imaging lens having a focal length of 230 mm, light of a wavelength of 589 nm reaches a focal position from, for example, 100 mm, away from the center 2c of the concentrating lens 2 in a direction perpendicular to the vertical axis Ax at a lens temperature of 20° C. However, at a lens temperature of 40° C., the focal position of the light is 236 mm from the concentrating lens 2. Accordingly, at a position of 230 mm away from the concentrating lens 2, the light passes through a position of 2.6 mm away from the vertical axis Ax in a direction perpendicular to the vertical axis Ax. Similar aberrations occur in all wavelengths of light. As a result, in accordance with a change in the lens temperature, the diameter of a concentrated light beam (beam of light constituted by concentrated light Lc) varies, which influences the output characteristics of the photovoltaic cell 3.

In this embodiment, since the secondary lens 100 is disposed opposite the photovoltaic cell 3, it can absorb a variation in the diameter of a concentrated light beam caused by a change in the temperature of the concentrating lens 2 (optical characteristics). Accordingly, how to arrange the optical characteristics (lens configuration) of the secondary lens 100 directly influences the power generation efficiency (photoelectric conversion efficiency) of the concentrating photovoltaic power generation apparatus 30, and such an arrangement of the optical characteristics (lens configuration) of the secondary lens 100 is a basic feature of this embodiment.

Although a silicone resin is used as a material for the concentrating lens 2, various light-transmitting materials may be used as a material for the concentrating lens 2. For example, an acrylic resin, such as PMMA (polymethyl methacrylate resin), polycarbonate, or glass may be used. Among these materials, glass is not usually used in terms of the workability. However, a resin material, such as PMMA, which is excellent in workability, has a problem that the refractive index is greatly dependent on the temperature, as in a silicone resin.

The concentrating lens 2 is formed as a concentric Fresnel lens which is concentrically formed and has a sawtooth cross section, from the viewpoint of making the concentrating lens 2 thinner and lighter and reducing the material cost and also improving the light-concentrating power factor and the molding workability. Although, in this case, a Fresnel lens is illustrated by way of example, a lens of a different shape may be applied as long as it can concentrate light Lc toward the secondary lens 100.

The outer periphery (outer frame) of the concentrating lens 2 is formed in a quadrilateral shape. The dimension of one side of the square is L1. The module frame 6 holds four concentrating lenses 2 arranged in two rows and two columns. A secondary lens 100, a photovoltaic cell 3, and a receiver substrate 4 are provided for each concentrating lens 2, and they are held by the common holding plate 5. The four concentrating lenses 2 (concentrating photovoltaic power generation apparatuses 30) are integrated in the holding plate 5 and the module frame 6. That is, the concentrating photovoltaic power generation module 30M of this embodiment includes four concentrating photovoltaic power generation apparatuses 30.

The configuration (optical characteristics) of the secondary lens 100 is defined in relation to the configuration (optical characteristics) of the concentrating lens 2. Thus, specific examples of the concentrating lens 2 applied to the third embodiment will be described below.

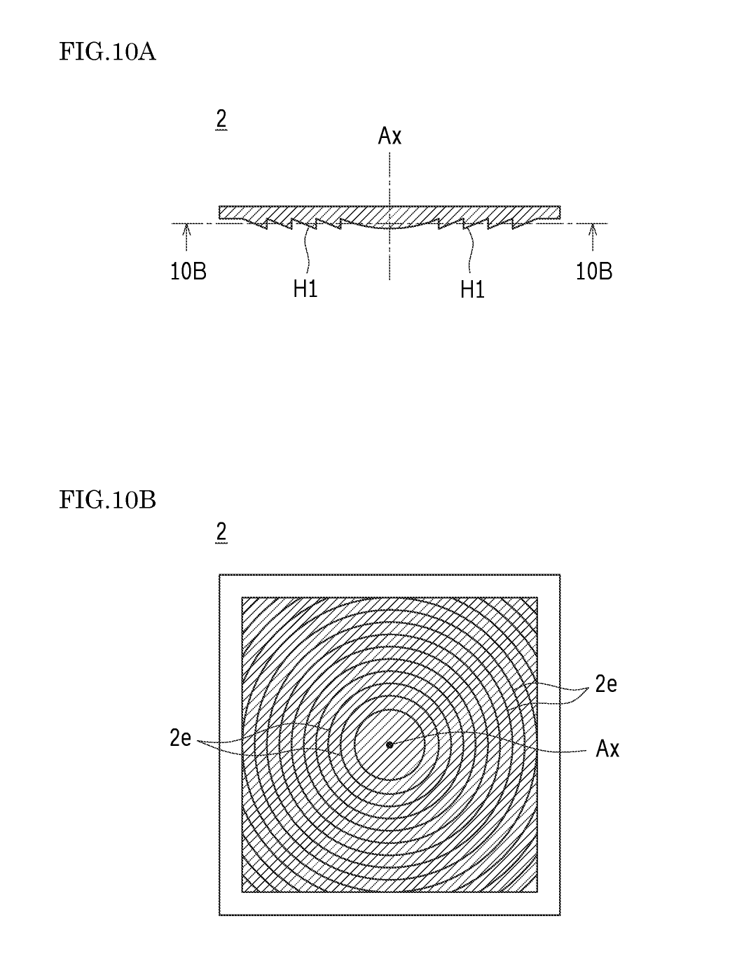

FIG. 10A is a sectional view of one concentrating lens 2 extracted from a cross section taken along line 9B-9B indicated by the arrows in FIG. 9A.

FIG. 10B is a sectional view of the concentrating lens 2 shown in FIG. 9A, taken along line 10B-10B of FIG. 10A.

The concentrating lens 2 concentrates light Lc toward the secondary lens 100 and the photovoltaic cell 3 disposed on the vertical axis Ax. The concentrating lens 2 is formed as a Fresnel lens, and the sawtooth of the Fresnel lens is formed concentrically in order to concentrate the light Lc. As the concentrating lens 2, either of an imaging type or a nonimaging type may be used.

In this embodiment, the positional relationship between the optical refractive face H1 defining the light-concentration characteristics of the concentrating lens 2 and the vertical axis Ax influences the configuration (optical characteristics) of the secondary lens 100. This will be discussed more specifically. When cutting the optical refractive faces H1 of the concentrating lens 2 in a plane (10B-10B indicated by the arrows) perpendicular to the vertical axis Ax, edge configurations 2e (line figures, in this case, circles represented by a plurality of concentric circles) appear as peripheries of a cross section (hatched figures shown in FIG. 10B: ring-like figures). In this case, similar figures (various circular shapes having different radii) of these edge configurations 2e are compared with the configuration of the secondary lens 100. That is, the relationship between similar figures of the edge configurations 2e and the configuration of the secondary lens 100 is one of the features of the present invention.

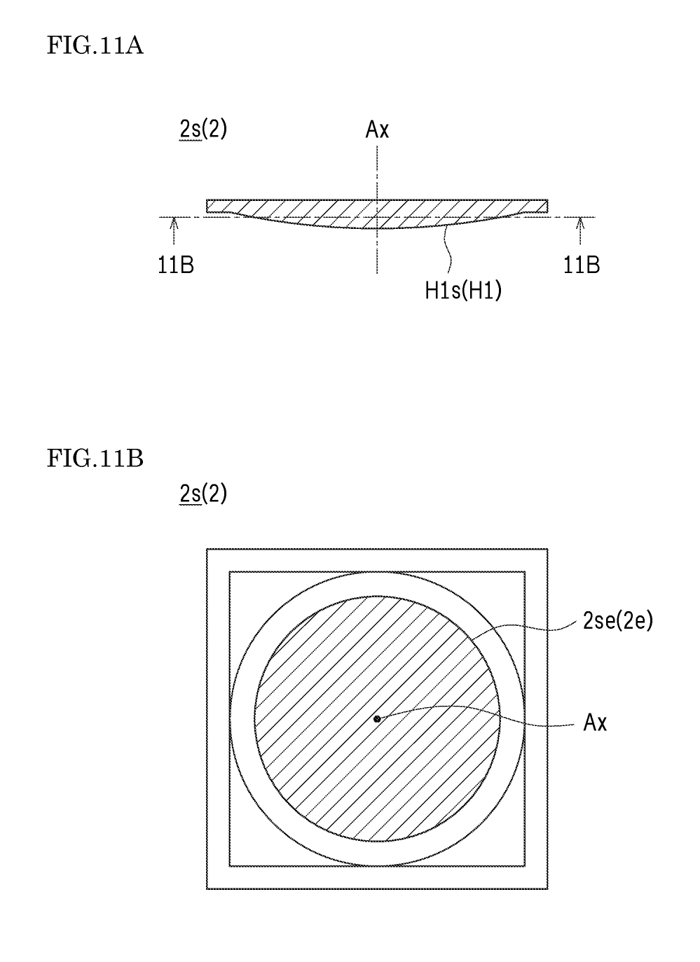

FIG. 11A is a sectional view of a concentrating lens 2s having a configuration different from that of the concentrating lens 2 shown in FIG. 10A, in a plane including the vertical axis Ax.

FIG. 11B is a sectional view of the concentrating lens 2s shown in FIG. 11A taken along line 11B-11B indicated by the arrows in FIG. 11A.

The concentrating lens 2s is a convex lens projecting to the photovoltaic cell 3. As in the concentrating lens 2, by using this type of concentrating lens 2s, the light Lc can be concentrated toward the secondary lens 100 and the photovoltaic cell 3 disposed on the vertical axis Ax. Accordingly, as a subject to be compared with the configuration of the secondary lens 100 is a line figure illustrating the relationship between an optical refractive face H1s defining the light-concentration characteristics of the concentrating lens 2s and the vertical axis Ax. More specifically, when cutting the optical refractive face H1s of the concentrating lens 2s in a plane (11B-11B indicated by the arrows) perpendicular to the vertical axis Ax, an edge configuration 2se (uniquely appearing circle) appears as an edge of a cross section (hatched figure shown in FIG. 11B: circular figure). A similar figure (circular shape) of this edge configurations 2e 2se is compared with the configuration of the secondary lens 100.

The concentrating lenses 2 and 2s concentrate light Lc toward the secondary lens 100 and the photovoltaic cell 3 disposed on the vertical axis Ax. Accordingly, the edge configurations 2e and the edge configuration 2se appearing as the edges of the cross sections (ring-like figures shown in FIG. 10B and circular figure shown in FIG. 11B) when cutting the optical refractive faces H1 and H1s in a plane (10B-10B indicated by the arrows in FIGS. 10A and 11B-11B indicated by the arrows in FIG. 11A) perpendicular to the vertical axis Ax appear as a circle (or a concentric circle). However, the configuration of the concentrating lenses 2 and 2s are not restricted to the above-described circular shape, and may be another shape as long as the concentrating lenses 2 and 2s are capable of concentrating light toward the vertical axis Ax.

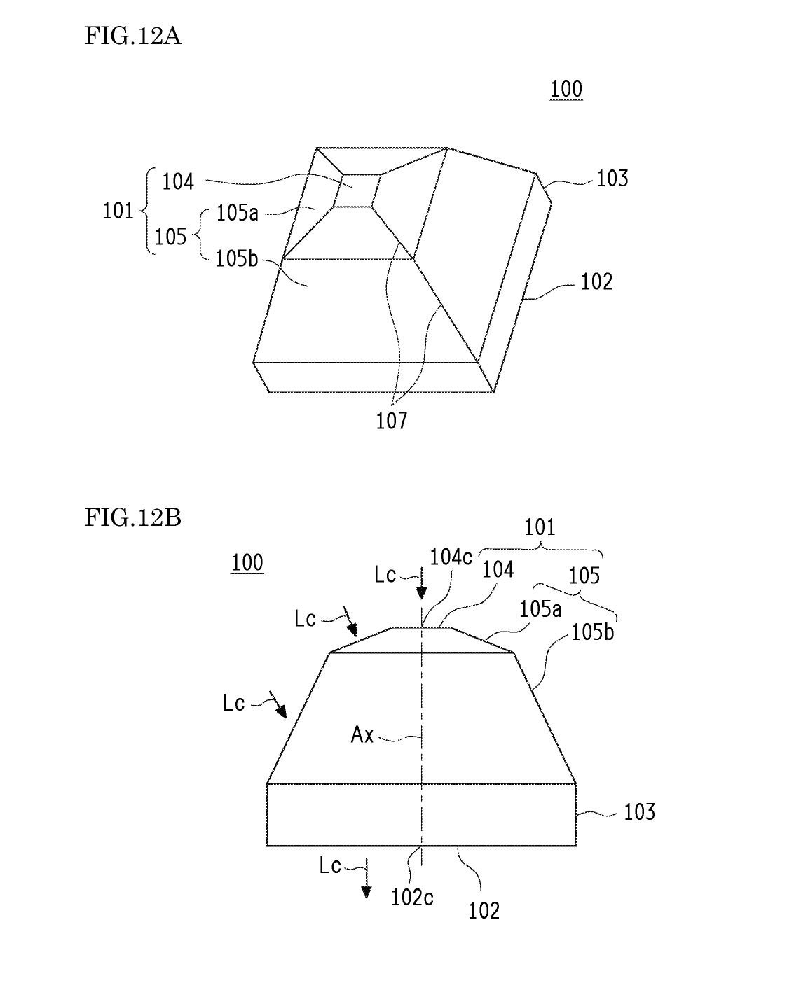

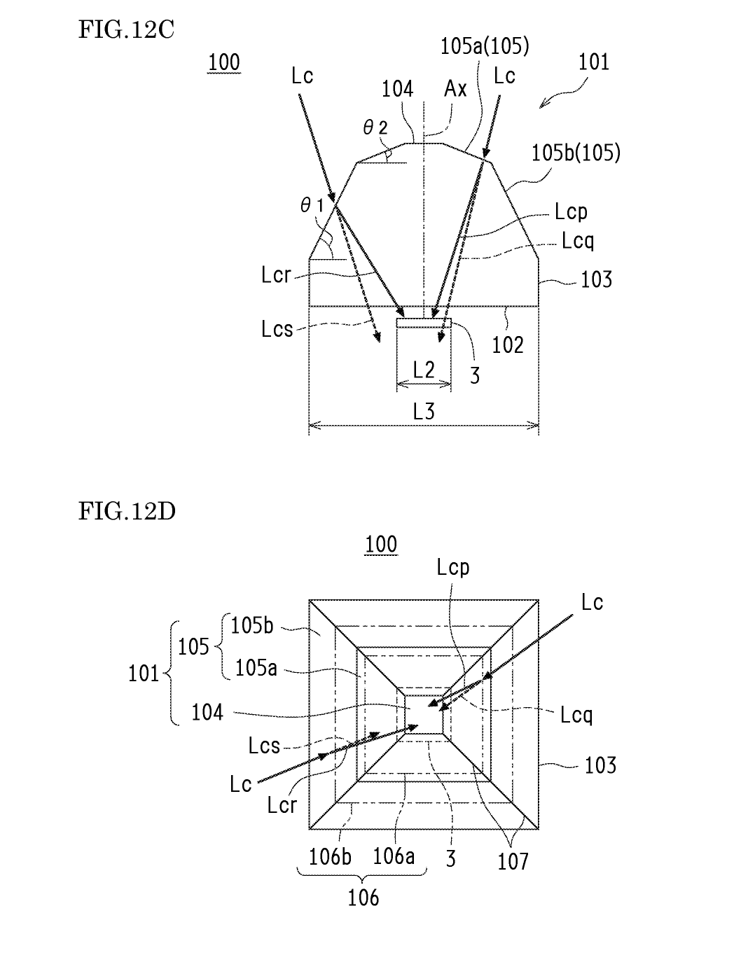

The reason why similar figures of edge configurations 2es (edge configurations 2e or edge configurations 2e 2se) are compared with the configuration of the secondary lens 100 is as follows. Since the size of the concentrating lens 2 or 2s and the size of the secondary lens 100 are relatively different, it is necessary to match the size of the concentrating lens 2 or 2s to the size of the secondary lens 100 when defining the optical characteristics (configuration) of the secondary lens 100 by comparing the two configurations with each other. When comparing the two configurations after the sizes thereof match each other, it is seen that an outer peripheral configuration 106 (see FIG. 12D) of a cross section of the secondary lens 100 is different from a similar figure of the edge configurations 2e or the edge configuration 2es of a cross section of the concentrating lens 2 or 2s.

The reason why the outer peripheral configurations of at least some cross sections of the secondary lens 100 are set to be different from a similar figure of the edge configurations (edge configurations 2e or edge configurations 2e 2se) is as follows. With this configuration, the surface of the secondary lens 100 obliquely crosses the advancing direction of the light Lc, as viewed from above (when viewing the secondary lens 100 in a direction of the vertical axis Ax), thereby making it possible to refract the light Lc.

When the concentrating lens 2 is a Fresnel lens (FIG. 10A) in which a plurality of optical refractive faces H1 are disposed in a ring-like shape, the edge configurations 2e obtained by cutting the optical refractive faces H1 of the concentrating lens 2 in a plane perpendicular to the vertical axis Ax (10B-10B indicated by the arrows in FIG. 10A) are circles (edge configurations 2e) extracted from a plurality of concentric circles. When the concentrating lens 2 is a lens (FIG. 11A) having a single convex refractive face at least one side, the edge configurations 2e 2se obtained by cutting the optical refractive face H1s of the concentrating lens 2s in a plane perpendicular to the vertical axis Ax (11B-11B indicated by the arrows in FIG. 11A) is a single circle (edge configurations 2e 2se). Hereinafter, the optical refractive faces H1 and H1s will not be distinguished from each other and will be simply referred to as the “optical refractive face H1”, and the edge configurations 2e and the edge configuration 2es will not be distinguished from each other and will be simply referred to as the “edge configurations 2e”.

FIG. 12A is a perspective view of the configuration of the secondary lens 100 of the third embodiment, as viewed from an obliquely upward direction.

FIG. 12B is a side view of the secondary lens 100 shown in FIG. 12A, as viewed from a side.

The secondary lens 100 includes a light incoming section 101 and a light outgoing section 102. The light incoming section 101 opposes the concentrating lens 2, and light Lc (incident light) concentrated by the concentrating lens 2 is incident on the light incoming section 101. The light outgoing section 102 opposes the photovoltaic cell 3, and the light Lc incident on the light incoming section 11 is output from the light outgoing section 102 to the photovoltaic cell 3. That is, the secondary lens 100 guides the incident light (light Lc) incident on the light incoming section 101 to the light outgoing section 102 and then applies the exit light (light Lc) from the light outgoing section 102 to the photovoltaic cell 3. The secondary lens 100 also includes a base portion 103, which serves as a waveguide, between the light incoming section 101 and the light outgoing section 102. The light incoming section 101, the light outgoing section 102, and the base portion 103 are integrally formed in order to implement high-precision optical characteristics as the secondary lens 100.

The light incoming section 101 includes a vertex portion 104 opposing the concentrating lens 2, an intermediate section 105a disposed (formed) continuously from the vertex portion 104, and an intermediate section 105b disposed (formed) continuously from the intermediate section 105a and opposing the light outgoing section 102. That is, the intermediate sections 105a and 105b form an intermediate portion 105 which is positioned between the vertex portion 104 and the light outgoing section 102 and on which the light Lc is incident. The intermediate sections 105a and 105b may be simply referred to as the “intermediate portion 105” unless it is necessary to distinguish them from each other. The light outgoing section 102 is formed in a planar shape and opposes the photovoltaic cell 3.

The base portion 103 is formed in a generally quadrilateral shape in accordance with a chip configuration of the photovoltaic cell 3. The intermediate section 105b is formed in a rectangular frustum since it is disposed continuously from the base portion 103, and the surface of the intermediate section 105b is constituted by four planes (refractive faces). The intermediate section 105a is also formed in a rectangular frustum, as well as the intermediate section 105b, since it is disposed continuously from the intermediate section 105b, and the surface of the intermediate section 105a is constituted by four planes (refractive faces).

The top end of the intermediate section 105a serves as the vertex portion 104, and the vertex portion 104 is formed in a quadrilateral shape. That is, the top end of the intermediate section 105a (rectangular frustum) serves as the vertex portion 104, the bottom end of the intermediate section 105a coincides with the top end of the intermediate section 105b, and the bottom end of the intermediate section 105b coincides with the base portion 103. The bottom end of the base portion 103 forms the light outgoing section 102.

Thus, the secondary lens 100 is formed in a three-dimensional mountain-like shape having one apex with respect to the light outgoing section 102. That is, the configuration of the intermediate portion 105 is as follows. The cross-sectional area of the intermediate portion 105 in a direction perpendicular to a straight line (generally, coincides with the vertical axis Ax) passing through a center 102c of the light outgoing section 102 and a center 104c of the vertex portion 104 increases as it approaches from the vertex portion 104 toward the light outgoing section 102. With this structure, the light Lc can be refracted or concentrated toward the photovoltaic cell 3.

The vertical axis Ax defined by the center 2c of the concentrating lens 2 and the center 3c of the photovoltaic cell 3 is adjusted to and substantially coincides with the straight line passing through the center 102c of the light outgoing section 102 and the center 104c of the vertex portion 104 of the secondary lens 100. Accordingly, the above-described straight line will be simply referred to as the “vertical axis Ax”.

The vertical axis Ax may deviate from the center 102c of the light outgoing section 102 and the center 104c of the vertex portion 104, depending on the overall configuration of the secondary lens 100. Generally, however, since the secondary lens 100 is adjusted, as a whole, to the vertical axis Ax, a description will be given below, assuming that the vertical axis Ax substantially coincides with a straight line passing through the center 102c of the light outgoing section 102 and the center 104c of the vertex portion 104. Even if there is a slight displacement, the operational effects are not changed.

The base portion 103 does not function as a lens. That is, the base portion 103 serves as a waveguide which simply guides the light Lc from the light incoming section 101 to the light outgoing section 102 without reflecting or dispersing the light Lc. Accordingly, when the receiver substrate 4 having the photovoltaic cell 3 mounted thereon is bonded and fixed to the secondary lens 100, even if a light-transmitting material of the light-transmitting-material filling portion 7 adheres to an outer peripheral surface of the base portion 103, the output characteristics of the photovoltaic cell 3 are not influenced at all.

Additionally, when positioning the secondary lens 100 (straight line passing through the center 102c of the light outgoing section 102 and the center 104c of the vertex portion 104) to the vertical axis Ax (concentrating lens 2 and photovoltaic cell 3), a jig or a suitable member can be correctly used by abutting it to an outer peripheral surface (side) of the base portion 103. Accordingly, because of the presence of the base portion 103, the manufacturing process for the concentrating photovoltaic power generation apparatus 30 can be simplified, thereby making it possible to more reliably and inexpensively perform the assembly of the concentrating photovoltaic power generation apparatus 30 (concentrating photovoltaic power generation module 30M).

Since the intermediate sections 105a and 105b of the intermediate portion 105 are formed in a rectangular frustum, each of them has ridge lines 107. Chamfering of the ridge lines 107 will be discussed later.

FIG. 12C is a conceptual view illustrating a state in which the light Lc concentrated by the concentrating lens 2 is concentrated and refracted when it is incident on the secondary lens 100, as viewed from a lateral side.

FIG. 12D is a conceptual view illustrating a state in which the light Lc concentrated by the concentrating lens 2 is concentrated and refracted when it is incident on the secondary lens 100, as viewed from the direction of the vertical axis Ax.

A width L3 of the secondary lens 100 (the bottom end of the light incoming section 101 (intermediate section 105b) and the base portion 103), that is, the length of one side of a quadrilateral, is set to be larger than the chip size of the photovoltaic cell 3, that is, a length L2 of one side of the chip (cell dimension L2). With this configuration, the light Lc can be guided (applied) to the entirety of the photovoltaic cell 3 (light-receiving surface of the cell).

The configuration of the light incoming section 101 is determined such that, part of the light Lc refracted and concentrated by the secondary lens 2, such as light Lcs, which would not inherently reach the photovoltaic cell 3, can reach the photovoltaic cell 3 by being refracted again by the secondary lens 100 (intermediate section 105b of the light incoming section 101).

That is, assuming that the secondary lens 100 is not disposed, the light Lcs of the light Lc concentrated by the concentrating lens 2 travels straight and is displaced from the photovoltaic cell 3. However, since the secondary lens 100 is disposed, the light Lcs reaches the photovoltaic cell 3 as light Lcr by being refracted by the intermediate section 105b having planar surfaces, thereby contributing to photoelectrical conversion.

Similarly, light Lcq, which would inherently travel straight to the photovoltaic cell 3, is refracted by the intermediate section 105a and is then applied to the photovoltaic cell 3 as light Lcp at a position displaced from the light Lcq.

That is, because of the presence of the intermediate portion 105 (secondary lens 100), the light Lc advancing toward the photovoltaic cell 3 is refracted again on the surface of the light incoming section 101 (intermediate portion 105). As a result, refraction of light Lc in a direction toward the axis Ax (see FIG. 12C), that is, in a direction in which the focal position is shifted, is generated, and also, refraction of the light Lc appearing when being projected on a plane perpendicular to the axis, as viewed from above (in FIG. 12D, refraction (horizontal refraction) which decreases the concentration of light in a plane intersecting with the vertical axis Ax) is generated. Thus, the light Lc concentrated toward the photovoltaic cell 3 is prevented from being excessively concentrated on and around the center of the photovoltaic cell 3.

A further description will be given of the outer configuration of the secondary lens 100 that refracts the light Lc and the operational effect based on this outer configuration.

At a position of the intermediate portion 105 (intermediate section 105a) at which the light Lcp is refracted, an outer peripheral configuration 106a of a cross section in a direction perpendicular to the vertical axis Ax can be extracted. The outer peripheral configuration 106a (and a surface including the outer peripheral configuration 106a) obliquely crosses the light Lc and thus refracts the light Lc. At a position of the intermediate portion 105 (intermediate section 105b) at which the light Lcr is refracted, an outer peripheral configuration 106b of a cross section in a direction perpendicular to the vertical axis Ax can be extracted. The outer peripheral configuration 106b (and a surface including the outer peripheral configuration 106b) obliquely crosses the light Lc and thus refracts the light Lc. Hereinafter, the outer peripheral configurations 106a and 106b may be referred to as the “outer peripheral configuration 106” when it is not necessary to distinguish them from each other.

That is, the outer peripheral configuration 106 (quadrilateral) is a configuration different from a similar figure (circle) of the edge configurations 2e (circles) obtained by cutting through the optical refractive face H1 of the concentrating lens 2 in a plane perpendicular to the vertical axis Ax. It is thus possible to refract the light Lc concentrated toward the vertical axis Ax and to prevent the light Lc from being excessively concentrated on and around the center of the photovoltaic cell 3.

Concerning the gradient of the surface of the intermediate portion 105 (intermediate sections 105a and 105b), the gradient of a portion closer to the light outgoing section 102 (intermediate section 105b) is greater than that of a portion closer to the vertex portion 104 (intermediate section 105a). That is, in the secondary lens 100, the gradient of the surface of the intermediate section 105b farther away from the vertical axis Ax is greater than that of the surface of the intermediate section 105a closer to the vertical axis Ax. Accordingly, the light Lc (light Lcs), which would be concentrated at a position far away from the center of the photovoltaic cell 3 (light-receiving surface) if the secondary lens 100 were not disposed, is refracted at a sharper angle so that it can be directed toward the photovoltaic cell 3 in a direction toward the vertical axis Ax, thereby improving the light-concentration efficiency. Additionally, the light Lc is refracted by both of the intermediate section 105a closer to the vertex portion 104 and the intermediate section 105b closer to the light outgoing section 102 which have different gradients, so as to change the focal position in the direction of the vertical axis Ax, thereby making it possible to decrease the concentration of the light Lc in the direction of the vertical axis Ax.

Since the intermediate sections 105a and 105b are formed in a rectangular frustum, the surfaces thereof have a certain angle of inclination. The gradient of the surface (angle of surface inclination) of the intermediate portion 105 (how much it is steep or gentle) may be defined by the angle between the surface of the intermediate portion 105 and a plane perpendicular to the vertical axis Ax.

Accordingly, a first angle of inclination θ1 (first angle of inclination θ1<90 degrees), which is the angle of surface inclination of the intermediate section 105b closer to the light outgoing section 102, is set to be greater than a second angle of inclination θ2, which is the angle of surface inclination of the intermediate section 105a closer to the vertex portion 104. That is, since the first angle of inclination θ1 is greater than the second angle of inclination θ2, the light Lc, which would reach a position far away from the photovoltaic cell 3 without the secondary lens 100, is refracted at a sharper angle, thereby improving the light-concentration characteristics.

As described above, the secondary lens 100 of this embodiment is the secondary lens 100 used in the concentrating photovoltaic power generation apparatus 30 that includes the photovoltaic cell 3 and the concentrating lens 2 which concentrates light Lc and applies it to the photovoltaic cell 3. The secondary lens 100 includes the light incoming section 101 on which the light Lc is incident and the light outgoing section 102 from which the light Lc incident on the light incoming section 101 is output to the photovoltaic cell 3. The light incoming section 101 also includes the vertex portion 104 opposing the concentrating lens 2 and the intermediate portion 105 positioned between the vertex portion 104 and the light outgoing section 102. Concerning the intermediate portion 105, the cross-sectional area of the intermediate portion 105 in a direction perpendicular to the vertical axis Ax which is defined by a straight line passing through the center 2c of the concentrating lens 2 and the center 3c of the photovoltaic cell 3 increases as it approaches from the vertex portion 104 toward the light outgoing section 102. The outer peripheral configurations 106 of at least some cross sections are different from a similar figure of the edge configurations 2e of a cross section obtained by cutting through the optical refractive face H1 of the concentrating lens 2 in a plane perpendicular to the vertical axis Ax.

Thus, in the secondary lens 100 of this embodiment, the cross-sectional area of the intermediate portion 105 (intermediate sections 105a and 105b) in a direction perpendicular to the vertical axis Ax which is defined by a straight line passing through the center 2c of the concentrating lens 2 and the center 3c of the photovoltaic cell 3 increases (monotonically increases) as it approaches from the vertex portion 104 toward the light outgoing section 102. Additionally, the outer peripheral configurations 106 (outer peripheral configurations 106a and 106b) of at least some cross sections are different from a similar figure of the edge configurations 2e of a cross section obtained by cutting through the optical refractive face H1 of the concentrating lens 2 in a plane perpendicular to the vertical axis Ax. With these configurations, the light Lc concentrated by the concentrating lens 2 toward the secondary lens 100 is refracted by an outer peripheral configuration 106 of the intermediate portion 105, thereby preventing the light Lc from being excessively concentrated on and around the photovoltaic cell 3. As a result, it is possible to suppress a decrease in FF (fill factor) which indicates the electrical characteristics of the photovoltaic cell 3 and to improve the power generation efficiency of the photovoltaic cell.

The outer peripheral configuration 106 of the secondary lens 100 is preferably formed as a polygon. Thus, in the secondary lens 100, since the outer peripheral configuration 106 is a polygon, a large amount of concentrated light Lc can be refracted on the individual sides of the polygon, thereby reliably decreasing the excessive concentration of light and further suppressing a decrease in the value of FF.

The polygon of the outer peripheral configuration 106 is preferably a regular polygon. The outer peripheral configuration 106 is not restricted to a quadrilateral which is formed when the secondary lens 100 is a rectangular frustum, but may be a hexagon or an octagon.

As stated above, it is sufficient if the surface of the intermediate portion 105 partially includes planes. That is, in the secondary lens 100, at least part of the surface of the intermediate portion 105 is preferably a plane. With this configuration, since the surface of the intermediate portion 105 includes a plane, the outer peripheral configuration 106 of a cross section of the intermediate portion 105 can be made different from a similar figure of the edge configurations 2e of a cross section of the concentrating lens 2 in a plane perpendicular to the vertical axis Ax.

A suitable amount of chamfering may be performed on the ridge lines 107 appearing on the surface of the intermediate portion 105. In this case, a polygon is considered as a pseudo-polygon, and such a pseudo-polygon is also included in a polygon of this embodiment. As chamfering, C-chamfering or R-chamfering is applicable.

That is, in the secondary lens 100, it is preferable that the surface of the intermediate portion 105 has ridge lines 107 and that the ridge lines 107 are chamfered. With this configuration, in the secondary lens 100, since the ridge lines of the intermediate portion 105 are chamfered, it is possible to prevent optical loss caused by scattering of light on the ridge lines 107 and to prevent the occurrence of damage (cracking or chipping) when handling the secondary lens 100 in a manufacturing process.

In the secondary lens 100, concerning the gradient of the surface of the intermediate portion 105, the gradient of the portion closer to the light outgoing section 102 (intermediate section 105b) is preferably greater than that of the portion closer to the vertex portion 104 (intermediate section 105a). With this configuration, in the secondary lens 100, the gradient of the surface of the intermediate portion 105 (intermediate section 105b) closer to the light outgoing section 102 is greater than that of the intermediate portion 105 (intermediate section 105a) closer to the vertex portion 104. Accordingly, the light Lc, which would reach a position far away from the center of the photovoltaic cell 3 (light-receiving surface) if the secondary lens 100 were not disposed, is refracted at a sharper angle toward the photovoltaic cell 3 in a direction toward the vertical axis Ax, thereby improving the light-concentration efficiency. Additionally, the light Lc is refracted by both of the intermediate portion 105 closer to the vertex portion 104 (intermediate section 105a) and the intermediate portion 105 closer to the light outgoing section 102 (intermediate section 105b) which have different gradients, so as to change the focal position in the direction of the vertical axis Ax, thereby making it possible to decrease the concentration of the light Lc in the direction of the vertical axis Ax (vertical direction). The definition of the angles of inclination has been discussed above.

More specifically, the first angle of inclination θ1, which is the angle of surface inclination of the portion closer to the light outgoing section 102 (intermediate section 105b), is preferably greater than the second angle of inclination θ2, which is the angle of surface inclination of the portion closer to the vertex portion 104 (intermediate section 105a). With this configuration, since the first angle of inclination θ1 of the surface of the intermediate portion 105 closer to the light outgoing section 102 (intermediate section 105b) is greater than the second angle of inclination θ2 of the surface of the intermediate portion 105 closer to the vertex portion 104 (intermediate section 105a), the light Lc (light Lcs), which would reach a position far away from the photovoltaic cell 3 without the secondary lens 100, is refracted at a sharper angle, thereby improving the light-concentration efficiency.

The vertex portion 104 of the secondary lens 100 is preferably a plane. With this configuration, since the vertex portion 104 is a plane, the secondary lens 100 reliably guides the light Lc concentrated toward the photovoltaic cell 3 to the photovoltaic cell 3 without excessively refracting the light Lc, thereby improving the light-concentration efficiency. It is also possible to decrease the concentration of the light Lc exhibited by the lens effect of the secondary lens 100, thereby further suppressing a decrease in the value of FF.

The vertex portion 104 of the secondary lens 100 may be a convex-shaped curved surface, instead of a plane. With this configuration, since the vertex portion 104 is a curved surface, the secondary lens 100 efficiently guides the light Lc concentrated on the vertex portion 104 by the concentrating lens 2 to the photovoltaic cell 3 while decreasing the concentration of the light Lc as a whole. It is thus possible to suppress a decrease in the value of FF and to suppress a decrease in the output current caused by a deviation of the angle of incidence of the light Lc or a positional displacement of the photovoltaic cell 3, thereby increasing the amount of power generation of the photovoltaic cell 3.

The secondary lens 100 preferably includes the base portion 103 which is disposed between the light outgoing section 102 and the intermediate portion 105 and which is integrally formed with the intermediate portion 105. With this configuration, since the secondary lens 100 includes the base portion 103 which is disposed between the light outgoing section 102 and the intermediate portion 105 and which is integrally formed with the intermediate portion 105, the secondary lens 100 can be handled through the use of the base portion 103. It is thus possible to facilitate the handling and molding of the secondary lens 100 in a manufacturing process without impairing the optical characteristics of the secondary lens 100, thereby rationalizing the manufacturing process and improving the production efficiency. As a result, a cost reduction in the parts can be achieved.

It is also preferable that the outer peripheries of the light outgoing section 102 and the base portion 103 of the secondary lens 100 are formed in a quadrilateral. With this configuration, in the secondary lens 100, since the outer peripheries of the light outgoing section 102 and the base portion 103 are formed in a quadrilateral, it is possible to perform manufacturing by efficiently arranging multiple secondary lenses 100 in a manufacturing process. Thus, the production efficiency in, for example, metallic molding, can be improved, thereby achieving a cost reduction in the parts. The light outgoing section 102 and the base portion 103 do not have to be a perfect quadrilateral, and may be a generally quadrilateral shape subjected to chamfering.

The height of the base portion 103 of the secondary lens 100 is preferably 0.5 mm or greater. With this configuration, a certain thickness of the secondary lens 100 is secured by setting the height of the base portion 103 (the length between the side of the intermediate portion 105 closer to the base portion 103 and the light outgoing section 102 (the thickness of the base portion 103)) to be 0.5 mm or greater. Thus, it is less likely to cause faults, such as chipping, while handling the secondary lens 100 by using a jig. Additionally, in the secondary lens 100, when the secondary lens 100 is brought to oppose the photovoltaic cell 3 with a light-transmitting material (light-transmitting-material filling portion 7) therebetween, even if a light-transmitting material of the light-transmitting-material filling portion 7 adheres to a lateral surface (base portion 103), optical loss does not occur.

The maximum height of the base portion 103 is set to be a suitable value by considering loss caused as a waveguide, the operability (handling characteristics), and a restriction imposed on the dimension between the light outgoing section 102 and the vertex portion 104. More specifically, if the secondary light-concentration distance from the point at which the vertex portion 104 of the secondary lens 100 intersects with the vertical axis Ax to the light-receiving surface of the photovoltaic cell 3 is indicated by Dd, the maximum height of the base portion 103 is determined such that the secondary light-concentration distance Dd satisfies predetermined conditions defined by the concentrating photovoltaic power generation apparatus 30.

An antireflection coat is preferably disposed on the surface of the light incoming section 101 of the secondary lens 100. With this configuration, since an antireflection coat is disposed on the surface of the light incoming section 101, the secondary lens 100 can prevent the concentrated light Lc from being reflected on the surface of the light incoming section 101 and reduce loss caused by surface reflection, thereby improving the output of the photovoltaic cell 3. Additionally, since an antireflection coat is disposed on the surface of the light incoming section 101, a lens material having a high refractive index (for example, 1.80 or higher) may be applicable.

The secondary lens 100 is preferably made from a light-transmitting optical material. The refractive index nD of the light-transmitting optical material with respect to a D-line (589.3 nm) is preferably greater than 1.35 and smaller than 1.80, and the absolute value of the temperature dependence of the refractive index is preferably smaller than 1×10⁻⁴.

With this configuration, in the secondary lens 100, since the refractive index ranges from 1.35 to 1.80, the advantages of the secondary lens 100 as a refracting element can be obtained, and the reflectance on the surface can be reduced, thereby maintaining the light-concentration efficiency at a high level. Additionally, even if the refractive index is changed due to a temperature rise accompanied by light concentration, fluctuations in the light-concentration characteristics can be suppressed, thereby securing stable optical characteristics and maintaining high efficiency.

As a material for the secondary lens 100, for example, borosilicate glass (typically, BK7 by Schott AG), may be used. The refractive index nD of BK7 is 1.517, and the temperature coefficient of the refractive index is −2×10⁻⁶. The material for the secondary lens 100 is not restricted to borosilicate glass, and a suitable light-transmitting material may be used. More specifically, a silicone resin or another type of optical glass, such as quartz glass, may be used. If the refractive index is low, a sufficient lens effect is not obtained, and if the refractive index is high, loss caused by surface reflection when light is incident on the secondary lens 100 is increased.

This will be discussed more specifically. If the secondary lens 100 is made from a material having a refractive index nD of 1.35, only a small lens effect is exhibited since the angle of refraction is smaller than that of BK7 by about 10%, in particular, the possibility that the light Lc incident on the outer side of the secondary lens 100 will not reach the photovoltaic cell 3 is high. In contrast, if the secondary lens 100 is made from a material having a refractive index nD of 1.80, the output of the photovoltaic cell 3 may be decreased since it is assumed that the reflection loss on the surface of the secondary lens 100 is increased by about 5%.

If the absolute value of the temperature dependence of the refractive index of a material used in the secondary lens 100, that is, the absolute value of the temperature coefficient of the refractive index of this material, is 1×10⁻⁴, the refractive index is changed by 0.01 if the temperature of the secondary lens 100 is increased by, for example, 100° C. Accordingly, if the refractive index nD is 1.50, the angle of refraction is changed by about 1% after the temperature is increased. As a result, the output stability may be influenced, such as the maximum light intensity value may be changed by about 5%, depending on the conditions.

A description has been given mainly of the secondary lens 100 of this embodiment. A description will now be given of a photovoltaic cell mounting body 1 using the secondary lens 100, a concentrating photovoltaic power generation apparatus 30 using the photovoltaic cell mounting body 1, and a concentrating photovoltaic power generation module 30M using the concentrating photovoltaic power generation apparatus 30.

The photovoltaic cell mounting body 1 of this embodiment is a photovoltaic cell mounting body including a secondary lens 100 on which light Lc concentrated by the concentrating lens 2 is incident, a photovoltaic cell 3 which opposes the secondary lens 100 and which performs photoelectric conversion on the light Lc output from the secondary lens 100, and a receiver substrate 4 on which the photovoltaic cell 3 is mounted. The secondary lens 100 is the secondary lens 100 of this embodiment. The light-transmitting-material filling portion 7 in which a light-transmitting material is filled is disposed between the secondary lens 100 and the photovoltaic cell 3.

Accordingly, since the photovoltaic cell mounting body 1 of this embodiment includes the light-transmitting-material filling portion 7 in which a light-transmitting material is filled between the secondary lens 100 and the photovoltaic cell 3, it eliminates an air space between the secondary lens 100 and the photovoltaic cell. With this configuration, since the reflection of light Lc at the interface between the secondary lens 100 and an air space can be suppressed, light Lc output from the secondary lens 100 can be efficiently guided to the photovoltaic cell 3, thereby enhancing the electrical characteristics of the photovoltaic cell.

The light-transmitting material filled into the light-transmitting-material filling portion 7 is, for example, a translucent resin material (such as a silicon resin) or an inorganic glass material.

In the photovoltaic cell mounting body 1, the thickness of the light-transmitting-material filling portion 7 is preferably from 0.3 mm to 2 mm. With this configuration, in the photovoltaic cell mounting body 1, since the thickness of the light-transmitting-material filling portion 7 formed between the secondary lens 100 and the photovoltaic cell 3 is preferably 0.3 mm to 2 mm, the controllability in a manufacturing process can be secured, and optical loss in the light-transmitting-material filling portion 7 can be reduced, thereby preventing a decrease in the light-guiding efficiency. As a result, required electrical characteristics can be secured.

That is, if the distance between the surface of the light outgoing section 102 and the surface of the photovoltaic cell 3 (thickness of the light-transmitting-material filling portion 7) is too small, the controllability in a manufacturing process is decreased. In contrast, if the distance is too large, the light-guiding efficiency may be reduced due to absorption or scattering of the light Lc on the light-transmitting-material filling portion 7. Accordingly, the thickness of the light-transmitting-material filling portion 7 is preferably about 0.3 mm to 2 mm.

The concentrating photovoltaic power generation apparatus 30 of this embodiment is the concentrating photovoltaic power generation apparatus 30 that includes the concentrating lens 2 which concentrates light Lc, the secondary lens 100 which outputs the light Lc incident from the concentrating lens 2, and the photovoltaic cell 3 which performs photoelectric conversion on the light Lc output from the secondary lens 100. The secondary lens is the secondary lens 100 of this embodiment.

Accordingly, in the concentrating photovoltaic power generation apparatus 30 of this embodiment, even if there is a deviation of the angle of incident light (light Lc) or an error in positioning the photovoltaic cell 3, the light Lc incident on the secondary lens 100 can be efficiently concentrated, and also, the excessive concentration of light can be prevented. It is thus possible to enhance the power generation efficiency of the photovoltaic cell (photovoltaic cell 3) and to improve the electrical characteristics.

It is now assumed that the dimension of one side of the concentrating lens 2 in a direction perpendicular to the vertical axis Ax is L1 (FIGS. 9A and 9B), the dimension of the photovoltaic cell 3 in a direction perpendicular to the vertical axis Ax is L2 (FIG. 12C), and the work distance between the concentrating lens 2 and the photovoltaic cell 3 is Wd (FIG. 9B). In this case, in the concentrating photovoltaic power generation apparatus 30 of this embodiment, when the secondary light-concentration distance from the point at which the vertex portion 104 of the secondary lens 100 intersects with the vertical axis Ax (point 104c in FIG. 12B) to the light-receiving surface of the photovoltaic cell 3 is Dd, Dd is preferably greater than Wd·L2/L1 by 1.2 to 1.8.

Thus, in the concentrating photovoltaic power generation apparatus 30 of this embodiment, it is possible to concentrate the light Lc incident on the secondary lens 100 with high efficiency and to prevent the excessive concentration of the light Lc with high precision, thereby enhancing the power generation efficiency of the photovoltaic cell (photovoltaic cell 3) and improving the electrical characteristics.

By setting the secondary light-concentration distance Dd to be greater than the value of Wd·L2/L1 by about 20% and to be smaller than twice of the value of Wd·L2/L1, a suitable distance can be secured. That is, by containing the secondary light-concentration distance Dd within a predetermined range Dd=(1.2 to 1.8) Wd·L2/L1, the optical characteristics can be improved, and problems (such as concerning productivity and manufacturing cost) of the secondary lens 100 in a manufacturing process can be solved.

For example, when the dimension L1 of one side of the concentrating lens 2 is 170 mm, the dimension L2 of the photovoltaic cell 3 is 5 mm, and the work distance Wd is 250 mm, Wd·L2/L1=250×5/170=7.35. If the secondary light-concentration distance Dd is calculated by selecting, for example, 1.4, from a coefficient range of 1.2 to 1.8, 7.35×1.4=10.29. Accordingly, the secondary light-concentration distance Dd is determined to be about 10 mm. The dimension of the plane of the base portion 103 is equal to the width L3 of the lens (L3=12 mm).

The concentrating photovoltaic power generation module 30M of this embodiment is a concentrating photovoltaic power generation module formed by combining a plurality of concentrating photovoltaic power generation apparatuses. Each of the concentrating photovoltaic power generation apparatuses is the concentrating photovoltaic power generation apparatus 30 of this embodiment. It is preferable that a plurality of concentrating lenses 2 are disposed on a single light-transmitting substrate (not shown) and that a plurality of photovoltaic cells 3 are disposed on the single holding plate 5.

Accordingly, in the concentrating photovoltaic power generation module 30M of this embodiment, positioning of the concentrating lenses 2 is performed on the single light-transmitting substrate, and positioning of the photovoltaic cells 3 is performed on the single holding plate 5. In this manner, by uniformly performing positioning of the concentrating lenses 2 and the photovoltaic cells 3, the concentrating photovoltaic power generation module 30M in which the concentrating lenses 2 and the photovoltaic cells 3 are highly precisely positioned can be easily manufactured. As a result, the productivity is improved, thereby reducing the manufacturing cost, and also, the electrical characteristics are improved.

In the concentrating photovoltaic power generation module 30M, the plurality of photovoltaic cells 3 are individually mounted on the associated receiver substrates 4, and the plurality of receiver substrates 4 are mounted on the holding plate 5. With this configuration, the concentrating photovoltaic power generation module 30M is manufactured by mounting the individual photovoltaic cells 3 on the respective receiver substrates 4, thereby making it easy to handle the photovoltaic cells 3. As a result, the operability is enhanced, thereby further improving the productivity.

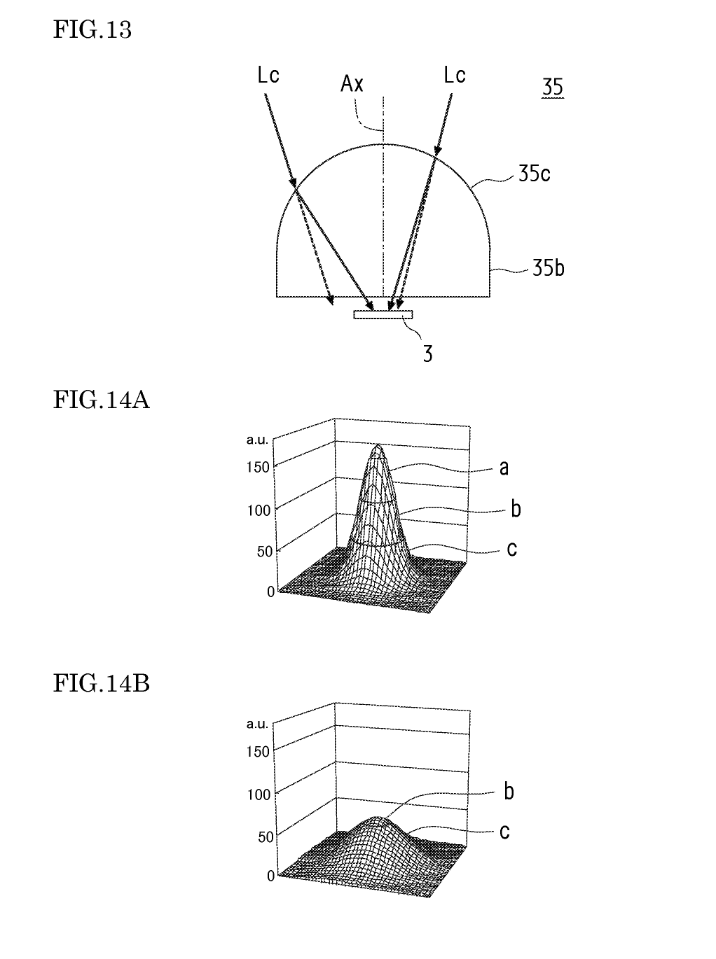

Then, the optical characteristics (light intensity distribution) of the secondary lens 100 of this embodiment will be compared with those of a comparative secondary lens 35 with reference to FIGS. 13 through 14B.

FIG. 13 is a conceptual view illustrating a state in which the light Lc concentrated by the concentrating lens 2 is concentrated and refracted when it is incident on the comparative secondary lens 35, which is a subject to be compared with the secondary lens 100, as viewed from a lateral side.

The comparative secondary lens 35, which is a subject to be compared with the secondary lens 100 of this embodiment, includes a light incoming section 35c on which the light Lc is concentrated and a base portion 35b which supports the light incoming section 35c. The light incoming section 35c corresponds to the light incoming section 101 of the secondary lens 100 and is formed in a hemispherical shape. That is, in the comparative secondary lens 35, the portion corresponding to the vertex portion 104 and the intermediate portion 105 of the secondary lens 100 is formed in a hemispherical shape. Because of this shape, an extremely large lens effect is produced on the light Lc.

In the comparative secondary lens 35, since the lens effect is produced on the incident light Lc by the light incoming section 35c, the light Lc is further concentrated toward the center and is further concentrated toward a narrower area when it is incident on the surface of the photovoltaic cell 3. That is, the value of FF of the electrical characteristics of the photovoltaic cell 3 may be decreased. Accordingly, without the use of the secondary lens 100, the light Lc refracted by the concentrating lens 2 toward the comparative secondary lens 35 may be concentrated on an extremely narrow area near the center of the photovoltaic cell 3, depending on the work distance Wd between the concentrating lens 2 and the photovoltaic cell 3, the wavelength of the light Lc, and the lens temperature. It is thus difficult to stably obtain a sufficient value of FF.

As discussed above, the secondary lens 100 of this embodiment includes the intermediate sections 105a and 105b formed by planes having two different angles of inclination, such as the first angle of inclination θ1 and the second angle of inclination θ2. Thus, the light Lc is refracted in accordance with each of the two different angles and is prevented from being excessively concentrated on and around the center of the photovoltaic cell 3.

That is, in the secondary lens 100, when light (light Lcq shown in FIG. 12C) directing toward the vertical axis Ax is incident on the secondary lens 100, it is refracted in the lateral direction and travels as light Lcp (FIG. 12C). Thus, the light Lcp does not pass through the vertical axis Ax. Accordingly, even if the conditions, such as the work distance Wd, are changed, a very small amount of light reaches the center of the photovoltaic cell 3, thereby preventing the concentration of light on the surface of the photovoltaic cell 3. It is thus possible to stably obtain a sufficient value of FF.

For example, without the use of the secondary lens 100 or the comparative secondary lens 35, if the light Lc concentrated by the concentrating lens 2 was directly applied to the photovoltaic cell 3, an output current of 2.5 A and an FF value of 0.80 were obtained. Additionally, under similar conditions, if the comparative secondary lens 35 was used, an output current of 2.6 A and an FF value of 0.60 were obtained. That is, because of the use of the comparative secondary lens 35, since the concentration of light toward the vertical axis Ax is intensified, the value of FF is decreased.

In contrast, under similar conditions, with the use of the secondary lens 100, an output current of 2.8 A and an FF value of 0.80 were obtained. That is, with the use of the secondary lens 100 of this embodiment, the output current was significantly improved while maintaining the value of FF. Thus, by the use of the secondary lens 100, the output current of the photovoltaic cell 3 can be maintained while suppressing an influence of a deviation of the angle of incident light Lc, an error in assembling the photovoltaic cell module, or an aberration caused by a change in the temperature of the concentrating lens 2.

Without the use of the secondary lens 100, if the lens temperature deviates by ±5° C. or if the angle of incidence deviates about ±0.2 degrees, loss of the output current reaches 5%. In contrast, optical simulations show that, with the use of the secondary lens 100 of the third embodiment, with each of the same deviation of the temperature and the same deviation of the angle of incidence, loss of the output current is contained within 2%.

FIG. 14A is a light-intensity distribution diagram which three-dimensionally illustrates an in-plane light intensity distribution on the photovoltaic cell 3 with the use of the comparative secondary lens 35.

FIG. 14B is a light-intensity distribution diagram which three-dimensionally illustrates an in-plane light intensity distribution on the photovoltaic cell 3 with the use of the secondary lens 100 of this embodiment.

In the case of the comparative secondary lens 35 (FIG. 14A), the maximum light intensity value exceeds 150 a.u. (arbitrary unit), and the intensity level a (100 to 150 a.u.) and the intensity level b (50 to 100 a.u.) protrude at the central portion, unlike the intensity level c (0 to 50 a.u.). Thus, the light Lc is concentrated at the central portion of the photovoltaic cell 3.

In the case of the secondary lens 100 (FIG. 14B), the maximum light intensity value is about 50 a.u., and the in-plane light intensity on the photovoltaic cell 3 is reduced to about one third. Thus, the above-described advantages are obtained.

### Fourth Embodiment

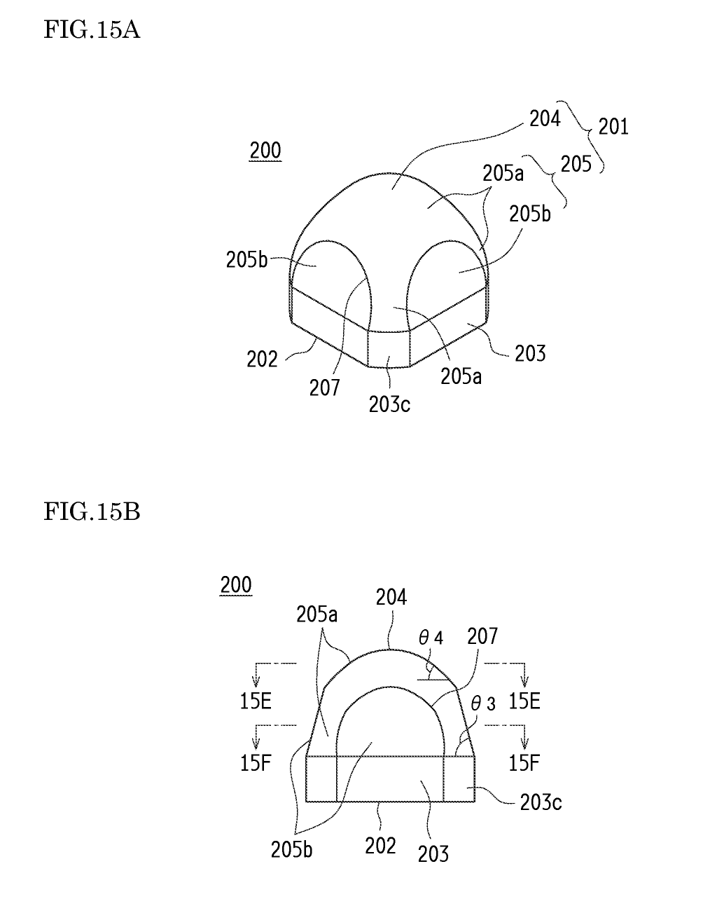

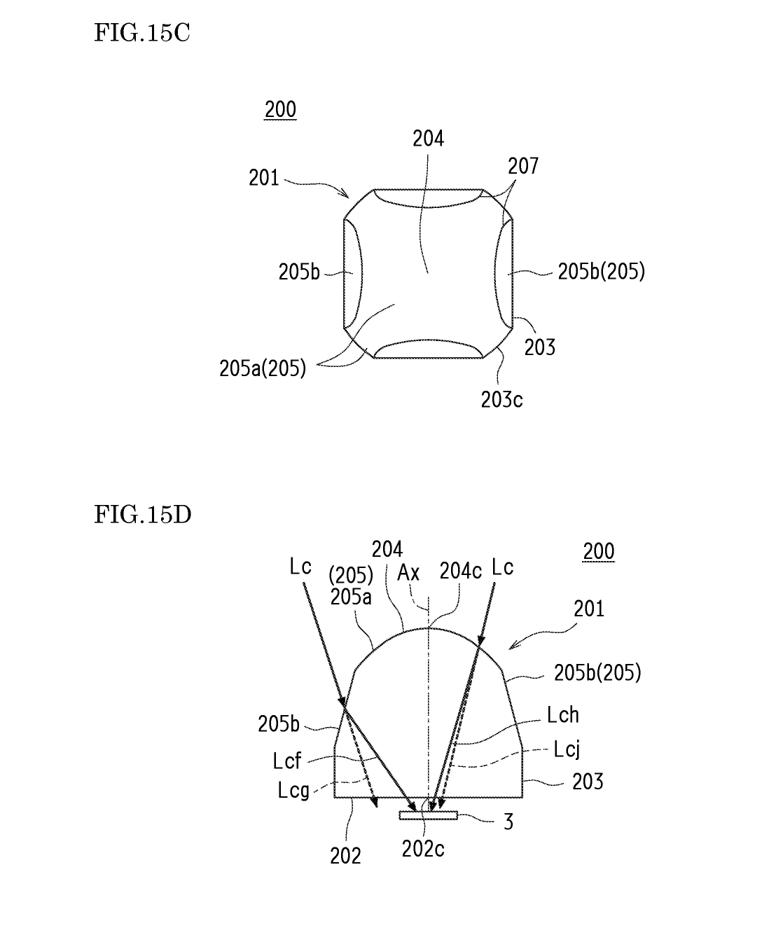

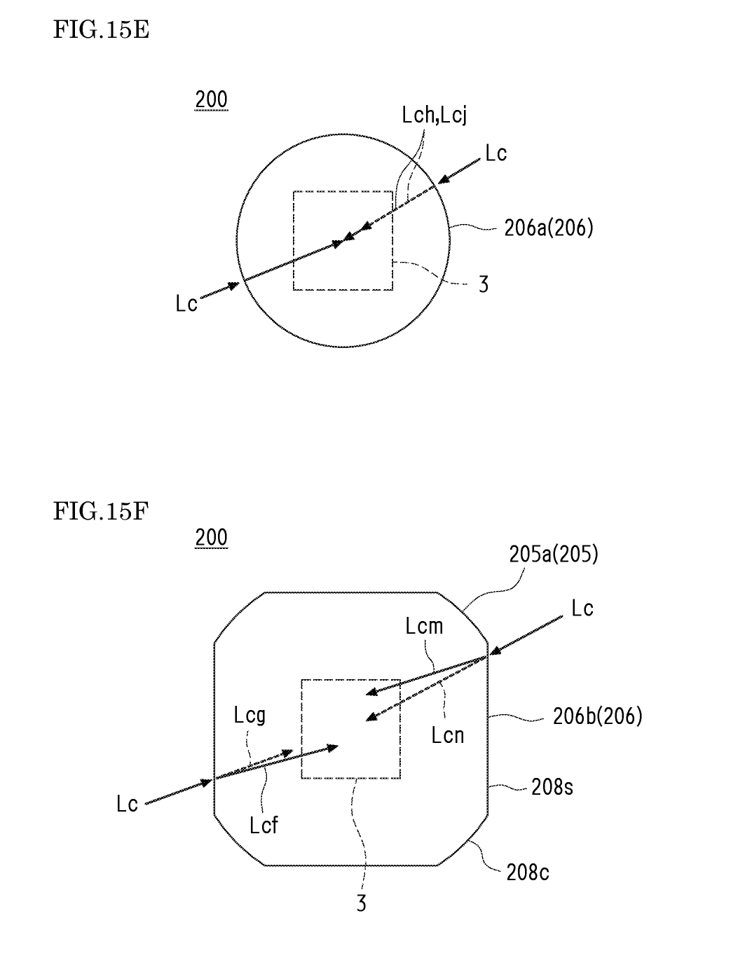

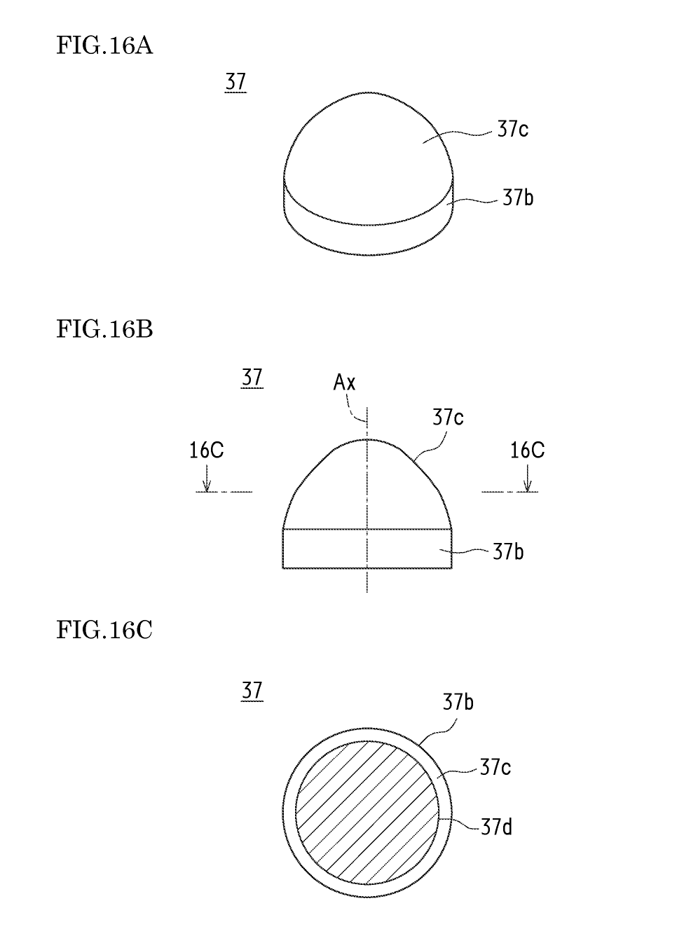

A secondary lens 200 of a fourth embodiment will be described below with reference to FIGS. 15A through 15F and FIGS. 16A through 16C. This embodiment is different from the third embodiment only in the configuration (effect) of the secondary lens 200. Accordingly, a description will be given mainly of portions of the secondary lens 200 different from those of the secondary lens 100. The concentrating photovoltaic power generation apparatus 30, the concentrating photovoltaic power generation module 30M, and the photovoltaic cell mounting body 1 are similar to those of the third embodiment, and an explanation thereof will thus be omitted.

FIG. 15A is a perspective view of the configuration of the secondary lens 200 of the fourth embodiment, as viewed from an obliquely upward direction.

FIG. 15B is a side view of the secondary lens 200 shown in FIG. 15A, as viewed from a side.

FIG. 15C is a plan view of the secondary lens 200 shown in FIG. 15A, as viewed from above.

The secondary lens 200 includes a light incoming section 201, a light outgoing section 202, and a base portion 203 which respectively correspond to the light incoming section 101, the light outgoing section 102, and the base portion 103 of the secondary lens 100 of the third embodiment. The light incoming section 201 includes a vertex portion 204 opposing the concentrating lens 2 and an intermediate portion 205 disposed between the vertex portion 204 and the light outgoing section 202.

The intermediate portion 205 includes an intermediate section 205a formed in a curved surface. The intermediate section 205a (curved surface) is formed in, for example, a hemispherical shape (hemisphere) including the vertex portion 204. The largest diameter portion (bottom end) is disposed opposite the light outgoing section 202 (base portion 203).

A boundary is not particularly necessary between the vertex portion 204 and the intermediate section 205a, and they are integrally and continuously formed as part of a hemisphere. More specifically, as viewed from a side, the curvature of the curved surface (curve appearing on a lateral surface) of the vertex portion 204 is greater than that of the curved surface (curve appearing on a lateral surface) of the intermediate section 205a (see a side view of a comparative secondary lens 37 having a curved surface of the same configuration as that of the secondary lens 200 (FIG. 16B)).

Although a description will be given, assuming that the intermediate section 205a is a hemispherical shape, the curved surface of the intermediate section 205a may have another configuration, for example, a configuration formed by the application of an ellipsoid or a configuration formed by providing more curvatures to the intermediate section 205a and by changing the curvature in a stepwise manner between the intermediate section 205a closer to the vertex portion 204 and the intermediate section 205a closer to the light outgoing section 202 (base portion 203).

The base portion 203 is basically a rectangular (quadrilateral) shape, as viewed from above (in a direction of the vertical axis Ax), and has a corner section 203c corresponding to vertices of the rectangle. The corner section 203c coincides with a segment of a circle formed at the largest diameter portion of the intermediate section 205a (hemisphere). The height (thickness) of the base portion 203 is similar to that of the base portion 103.

The intermediate portion 205 is integrated into the base portion 203, and the outer peripheral configuration of the bottom end of the intermediate portion 205 and that of the top end of the base portion 203 coincide with each other. Accordingly, at the largest diameter portion of the intermediate section 205a (portion continuously provided from the base portion 203), the side portions between the four corner sections 203c (portions other than the corner sections 203c) coincide with the lateral surfaces (planes) of the base portion 203, and they are cut by planes (intermediate sections 205b). That is, at the bottom end of the intermediate section 205a, part of the circle (hemisphere) is cut by the intermediate sections 205b, and the bottom end of the intermediate section 205a coincides with the lateral surfaces (planes) of the base portion 203.

The intermediate portion 205 has planes (intermediate sections 205b) which are raised from the lateral surfaces of the base portion 203 toward the hemispherical intermediate section 205a and which cut part of the hemisphere. The intermediate sections 205b cut the bottom end of the hemispherical intermediate section 205a at four locations, and the cut portions are adjusted to the four planes (lateral surfaces) of the base portion 203. In this manner, the intermediate sections 205b serve as wall surfaces which are symmetrically disposed at four locations.

The intermediate sections 205b have a first angle of inclination θ3 defined between the intermediate sections 205b and a plane perpendicular to the vertical axis Ax (first angle of inclination θ3<90 degrees). The intermediate sections 205b tilting at the first angle of inclination θ3 is closer to the vertical axis Ax than the intermediate section 205a (having a second angle of inclination θ4) closer to the vertex portion 204. By comparison with the first angle of inclination θ3, the second angle of inclination θ4, which is the angle of surface inclination closer to the vertex portion 204, is defined at a position near line 15E-15E indicated by the arrows (FIG. 15B). The second angle of inclination θ4 does not necessarily have to be defined at a position of line 15E-15E indicated by the arrows, and may be defined at a suitable position of the intermediate portion 205 closer to the vertex portion 204.

In the intermediate portion 205, ridge lines 207 are formed between the intermediate section 205a and the intermediate sections 205b. The ridge lines 207 may be suitably chamfered, as in the ridge lines 107.

FIG. 15D is a conceptual view illustrating a state in which the light Lc concentrated by the concentrating lens 2 is concentrated and refracted when it is incident on the secondary lens 200, as viewed from a lateral side.

FIG. 15E is a conceptual view illustrating a state in which the light Lc concentrated by the concentrating lens 2 is concentrated and refracted when it is incident on the secondary lens 200 at a position of line 15E-15E indicated by the arrows in FIG. 15B, as viewed from the direction of the vertical axis Ax.

FIG. 15F is a conceptual view illustrating a state in which the light Lc concentrated by the concentrating lens 2 is concentrated and refracted when it is incident on the secondary lens 200 at a position of line 15F-15F indicated by the arrows in FIG. 15B, as viewed from the direction of the vertical axis Ax.

In the secondary lens 200, a cross section of the intermediate section 205a closer to the vertex portion 204 in a direction perpendicular to the vertical axis Ax (at a position of line 15E-15E indicated by the arrow in FIG. 15B) has an outer peripheral configuration 206a (FIG. 15E).

Since the basic configuration of the intermediate section 205a is a hemisphere, a hemispherical cross section (end face) appears, and thus, the outer peripheral configuration 206a of the intermediate section 205a closer to the vertex portion 204 is circular. Since the edge configurations 2e of the concentrating lens 2 are circles about the vertical axis Ax, the light Lc is incident perpendicularly to the surface of the outer peripheral configuration 206a at an incident point of the outer peripheral configuration 206a without obliquely crossing the surface of the outer peripheral configuration 206a.

Accordingly, the light Lc incident on the outer peripheral configuration 206a travels straight, as viewed from above (FIG. 15E). As viewed from a side, however, the light Lc from the concentrating lens 2 does not travel straight as light Lcj, and instead, it is refracted by the intermediate section 205a and travels as light Lch in a direction in which the focal position is shifted (FIG. 15D). That is, the secondary lens 200 (intermediate section 205a) produces a lens effect on the light Lc, thereby performing required concentration of the light Lc.

In the secondary lens 200, a cross section including the intermediate section 205b in a direction perpendicular to the vertical axis Ax (at a position of line 15F-15F indicated by the arrow in FIG. 15B) has an outer peripheral configuration 206b (FIG. 15F). At a position corresponding to the outer peripheral configuration 206b, the light incoming section 201 includes the intermediate sections 205b (planes) and curved surfaces formed by the intermediate section 205a. Accordingly, the outer peripheral configuration 206b is a configuration having straight lines 208s and curved lines 208c.

The curved lines 208c coincide with the surface configuration of a hemisphere (segments, which are part of a circle) of the intermediate section 205a. Accordingly, the secondary lens 200 produces a regular lens effect on the light Lc, thereby maintaining the balance between light concentration and refraction.

If it is assumed that the secondary lens 200 is not provided, part of the light Lc concentrated by the concentrating lens 2, such as, light Lcg, travels straight and deviates from the direction to the photovoltaic cell 3. Because of the presence of the secondary lens 200, however, due to the refraction effect of the intermediate section 205b having a plane surface, the light Lcg changes the direction and reaches the photovoltaic cell 3 as light Lcf, thereby contributing to photoelectric conversion (FIGS. 15D and 15F). Since the light Lc is input such that it obliquely crosses the intermediate section 205b, which is a plane, the refraction effect is produced, both as viewed from a side (FIG. 15D) and as viewed from above (FIG. 15F).

The degree of refraction is changed in accordance with the positional relationship between the light Lc and the outer peripheral configuration 206b (intermediate section 205b). For example, light Lcn assumed to travel straight is refracted by the outer peripheral configuration 206b and travels as light Lcm, thereby preventing excessive concentration of the light Lc on and around the center of the photovoltaic cell 3.

As described above, the secondary lens 200 of this embodiment is the secondary lens 200 used in the concentrating photovoltaic power generation apparatus 30 that includes the photovoltaic cell 3 and the concentrating lens 2 which concentrates light Lc and applies it to the photovoltaic cell 3. The secondary lens 200 includes the light incoming section 201 on which the light Lc is incident and the light outgoing section 202 from which the light Lc incident on the light incoming section 201 is output to the photovoltaic cell 3. The light incoming section 201 also includes the vertex portion 204 opposing the concentrating lens 2 and the intermediate portion 205 positioned between the vertex portion 204 and the light outgoing section 202. The cross-sectional area of the intermediate portion 205 in a direction perpendicular to the vertical axis Ax which is defined by a straight line passing through the center 2c of the concentrating lens 2 and the center 3c of the photovoltaic cell 3 increases as it approaches from the vertex portion 204 toward the light outgoing section 202. The outer peripheral configurations 206 (outer peripheral configuration 206b (FIG. 15F)) of at least some cross sections are different from a similar figure of the edge configurations 2e of a cross section obtained by cutting through the optical refractive face H1 of the concentrating lens 2 in a plane perpendicular to the vertical axis Ax.

In the secondary lens 200 of this embodiment, the cross-sectional area of the intermediate portion 205 (intermediate sections 205a and 205b) in a direction perpendicular to the vertical axis Ax which is defined by a straight line passing through the center 2c of the concentrating lens 2 and the center 3c of the photovoltaic cell 3 increases (monotonically increases) as it approaches from the vertex portion 204 toward the light outgoing section 202. Additionally, the outer peripheral configurations 206 (outer peripheral configuration 206b) of at least some cross sections are different from a similar figure of the edge configurations 2e of a cross section obtained by cutting through the optical refractive face H1 of the concentrating lens 2 in a plane perpendicular to the vertical axis Ax. With this configuration, the light Lc concentrated by the concentrating lens 2 toward the secondary lens 200 is refracted by an outer peripheral configuration 206 (outer peripheral configuration 206b) of the intermediate portion 205, thereby preventing the light Lc from being excessively concentrated on and around the center of the photovoltaic cell 3. As a result, it is possible to suppress a decrease in FF (fill factor) which indicates the electrical characteristics of the photovoltaic cell 3 and to improve the power generation efficiency of the photovoltaic cell.

In the secondary lens 200, the outer peripheral configuration 206b includes the straight lines 208s and the curved lines 208c, and it is preferable that the straight lines 208s make up half or more of the outer peripheral length of the outer peripheral configuration 206b. Accordingly, in the secondary lens 200, the light Lc concentrated by the concentrating lens 2 toward the secondary lens 200 can be refracted by the straight lines 208s of the outer peripheral configuration 206b. Thus, even if the outer peripheral configuration 206b is not a polygon, the light Lc is refracted by the straight lines 208s, which make up half or more of the outer peripheral length, thereby reliably preventing the excessive concentration of the concentrated light Lc on and around the center of the photovoltaic cell 3. As a result, a decrease in the concentration of light is implemented.

In the secondary lens 200, it is preferable that at least part of the surface of the intermediate portion 205 is a plane (intermediate section 205b). With this configuration, in the secondary lens 200, since the surface of the intermediate section 205b includes a plane, the outer peripheral configuration 206b of a cross section of the intermediate section 205b can be made different from a similar figure of the edge configurations 2e of a cross section of the concentrating lens 2 in a plane perpendicular to the vertical axis Ax.

In the secondary lens 200, it is preferable that at least part of the surface of the intermediate portion 205 is a curved surface (intermediate section 205a). With this configuration, in the secondary lens 200, since the surface of the intermediate portion 205 (intermediate section 205a) includes a curved surface, part of the light Lc concentrated toward the photovoltaic cell 3 can be efficiently guided to the photovoltaic cell 3, thereby suppressing a decrease in the output current caused by a deviation of the angle of incident light or an error in assembling the photovoltaic cell 3 and thereby increasing the amount of power generation of the photovoltaic cell 3. That is, while decreasing the concentration of solar radiation by refraction, the balance between a decrease in the concentration of solar radiation and an increase in the light-concentration characteristics, which is another role of the secondary lens 200, can be implemented.

In the secondary lens 200, it is preferable that the outer peripheral configuration 206a (outer peripheral configuration 206) of the curved surface (intermediate section 205a) closer to the vertex portion 204 is circular about the vertical axis Ax. With this configuration, in the secondary lens 200, since the outer peripheral configuration 206a of the intermediate section 205a of a cross section closer to the vertex portion 204 is circular about the vertical axis Ax, the light-concentration efficiency becomes high in the central region of the secondary lens on which the light Lc is most intensively concentrated, thereby improving the light-concentration precision and suppressing a decrease in the output current. As a result, the amount of power generation of the photovoltaic cell 3 can be improved.

In the secondary lens 200, it is preferable that at least part of the outer peripheral configuration 206 (outer peripheral configuration 206b) is a segment (intermediate section 205a shown in FIG. 15F) forming part of a circle about the vertical axis Ax. With this configuration, in the secondary lens 200, since part of the outer peripheral configuration 206b is a segment forming part of a circle about the vertical axis Ax, the light Lc concentrated by the concentrating lens 2 can be efficiently guided to the photovoltaic cell 3, thereby suppressing a decrease in the output current caused by a deviation of the angle of incident light or an assembling error. At the same time, the concentration of the light Lc is decreased by refraction at portions other than the segments. As a result, the power generation efficiency of the photovoltaic cell 3 can further be improved.

In the secondary lens 200, it is preferable that the surface of the intermediate portion 205 has ridge lines 207 and that the ridge lines 207 are chamfered. With this configuration, in the secondary lens 200, since the ridge lines of the intermediate portion 205 are chamfered, it is possible to prevent optical loss caused by scattering of light on the ridge lines 207 and to prevent the occurrence of damage (cracking or chipping) when handling the secondary lens 200 in a manufacturing process.

In the secondary lens 200, it is preferable that the outer peripheral configuration 206a (FIG. 15E) of a cross section of the intermediate portion 205 closer to the vertex portion 204 is not similar to the outer peripheral configuration 206b (FIG. 15F) of a cross section of the intermediate portion 205 closer to the light outgoing section 202. With this configuration, in the secondary lens 200, the optical characteristics of the intermediate portion 205 closer to the vertex portion 204 are made different from those of the intermediate portion 205 closer to the light outgoing section 202. Accordingly, by utilizing characteristics in which the position at which light refracted by the concentrating lens 2 is incident varies in accordance with the wavelength, the balance between a decrease in the concentration of light and an increase in the light-concentration efficiency can be maintained.

In the secondary lens 200, the gradient of the intermediate portion 205 closer to the light outgoing section 202 is preferably greater than that of the intermediate portion 205 closer to the vertex portion 204. With this configuration, in the secondary lens 200, since the gradient of the surface of the intermediate portion 205 closer to the light outgoing section 202 is greater than that of the intermediate portion 205 closer to the vertex portion 204, the light Lc, which would reach a position far away from the center of the photovoltaic cell 3 (light-receiving surface) if the secondary lens 200 were not disposed, is refracted at a sharper angle toward the photovoltaic cell 3 in a direction toward the vertical axis Ax, thereby improving the light-concentration efficiency. Additionally, the light Lc is refracted by both of the intermediate portion 205 closer to the vertex portion 204 and the intermediate portion 205 closer to the light outgoing section 202 which have different gradients, so as to change the focal position in the direction of the vertical axis Ax, thereby making it possible to decrease the concentration of the light Lc in a direction of the vertical axis Ax (vertical direction). The gradients of the surface of the intermediate portion 205 may be defined in a manner similar to those in the third embodiment.

More specifically, in the secondary lens 200, the first angle of inclination θ3 (FIG. 15B), which is the angle of surface inclination of the intermediate portion 205 closer to the light outgoing section 202, is preferably greater than the second angle of inclination θ4 (FIG. 15B), which is the angle of surface inclination of the intermediate portion 205 closer to the vertex portion 204. With this configuration, in the secondary lens 200, since the first angle of inclination θ3 of the surface of the intermediate portion 205 closer to the light outgoing section 202 (for example, the intermediate section 205b) is greater than the second angle of inclination θ4 of the surface of the intermediate portion 205 closer to the vertex portion 104 (intermediate section 205a), the light Lc (light Lcg), which would reach a position far away from the photovoltaic cell 3 without the secondary lens 200, is refracted at a sharper angle, thereby improving the light-concentration efficiency.

The vertex portion 204 of the secondary lens 200 is preferably a convex-shaped curved surface. With this configuration, since the vertex portion 204 is a curved surface, the secondary lens 200 efficiently guides the light Lc concentrated on the vertex portion 204 by the concentrating lens 2 to the photovoltaic cell 3 while decreasing the concentration of the light Lc as a whole. It is thus possible to suppress a decrease in the value of FF and to suppress a decrease in the output current caused by a deviation of the angle of incidence of the light Lc or a positional displacement of the photovoltaic cell 3, thereby increasing the amount of power generation of the photovoltaic cell 3.

Alternatively, the vertex portion 204 of the secondary lens 200 may be a plane. With this configuration, since the vertex portion 204 is a plane, the secondary lens 200 reliably guides the light Lc concentrated toward the photovoltaic cell 3 to the photovoltaic cell 3 without excessively refracting the light Lc, thereby improving the light-concentration efficiency. It is also possible to decrease the concentration of the light Lc exhibited by the lens effect of the secondary lens 200, thereby further suppressing a decrease in the value of FF.

The secondary lens 200 preferably includes the base portion 203 which is disposed between the light outgoing section 202 and the intermediate portion 205 and which is integrally formed with the intermediate portion 205. With this configuration, since the secondary lens 200 includes the base portion 203 which is disposed between the light outgoing section 202 and the intermediate portion 205 and which is integrally formed with the intermediate portion 205, the secondary lens 200 can be handled through the use of the base portion 203. It is thus possible to facilitate the handling and molding of the secondary lens 200 in a manufacturing process without impairing the optical characteristics of the secondary lens 200, thereby rationalizing the manufacturing process and improving the production efficiency. As a result, a cost reduction in the parts can be achieved.

It is also preferable that the outer peripheries of the light outgoing section 202 and the base portion 203 of the secondary lens 200 are formed in a quadrilateral. With this configuration, in the secondary lens 200, since the outer peripheries of the light outgoing section 202 and the base portion 203 are formed in a quadrilateral, it is possible to perform manufacturing by efficiently arranging multiple secondary lenses 200 in a manufacturing process. Thus, the production efficiency can be improved, thereby achieving a cost reduction in the parts. The light outgoing section 202 and the base portion 203 do not have to be a perfect quadrilateral, and may be a generally quadrilateral shape subjected to chamfering or may have a curved surface, such as the corner section 203c (see FIG. 15A) continuously disposed from the bottom end of the intermediate section 205a.

The height of the base portion 203 of the secondary lens 200 is preferably 0.5 mm or greater. With this configuration, advantages similar to those obtained by the secondary lens 100 of the third embodiment are achieved by the secondary lens 200.

As in the secondary lens 100, the secondary lens 200 may preferably include an antireflection coat. The secondary lens 200 may preferably be made from a light-transmitting optical material similar to that forming the secondary lens 100.

Then, the optical characteristics (light intensity distribution) of the secondary lens 200 of this embodiment will be compared with those of a comparative secondary lens 37 with reference to FIGS. 16A through 16C.

FIG. 16A is a perspective view of the configuration of the comparative secondary lens 37, as viewed from an obliquely upward direction.

FIG. 16B is a side view of the comparative secondary lens 37, as viewed from a side.

FIG. 16C is a sectional view of the comparative secondary lens 37 at a position of line 16C-16C indicated by the arrows in FIG. 16B.

The comparative secondary lens 37 has a configuration from which the intermediate sections 205b of the secondary lens 200 of this embodiment are removed. Accordingly, the basic configuration of the comparative secondary lens 37 is a hemisphere. The comparative secondary lens 37 includes a light incoming section 37c which produces a lens effect and a base portion 37b which supports the light incoming section 37c. Configurations of horizontal cross sections 37d in a plane perpendicular to the vertical axis Ax are all circles (FIG. 16C).

The maximum light intensity value in the in-plane cell surface of the photovoltaic cell 3 of the secondary lens 200 was compared with that of the comparative secondary lens 37. As a result, it was possible to reduce the light intensity in the case of the use of the secondary lens 200 by about 20% compared with that in the case of the use of the comparative secondary lens 37.

### Fifth Embodiment

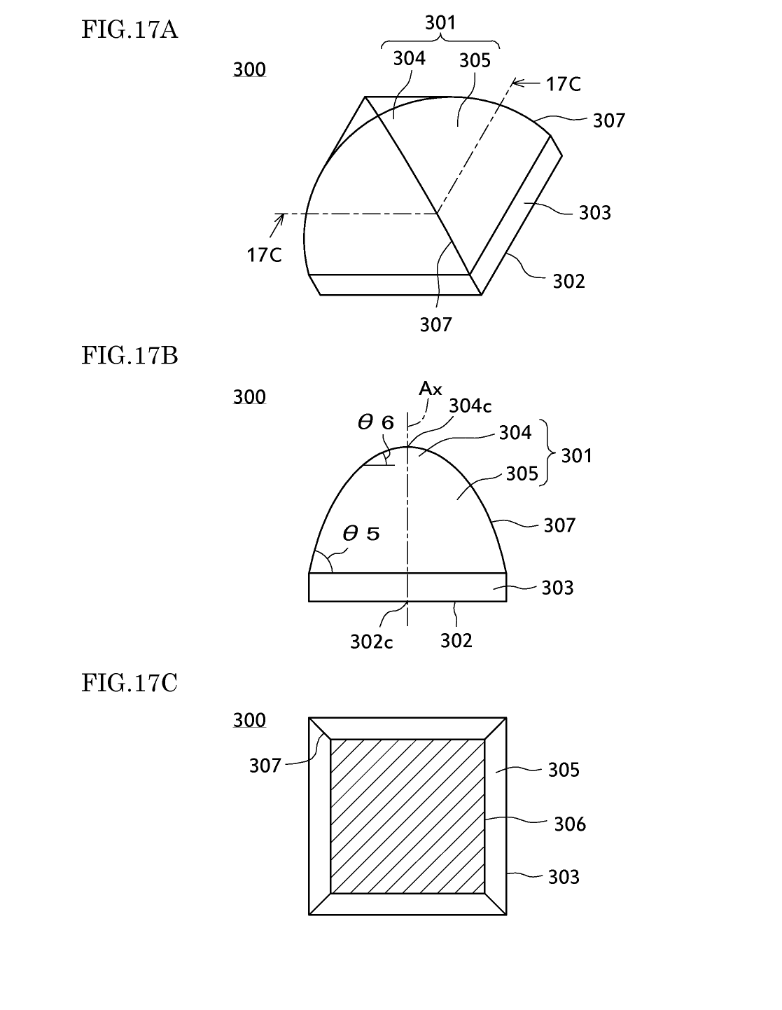

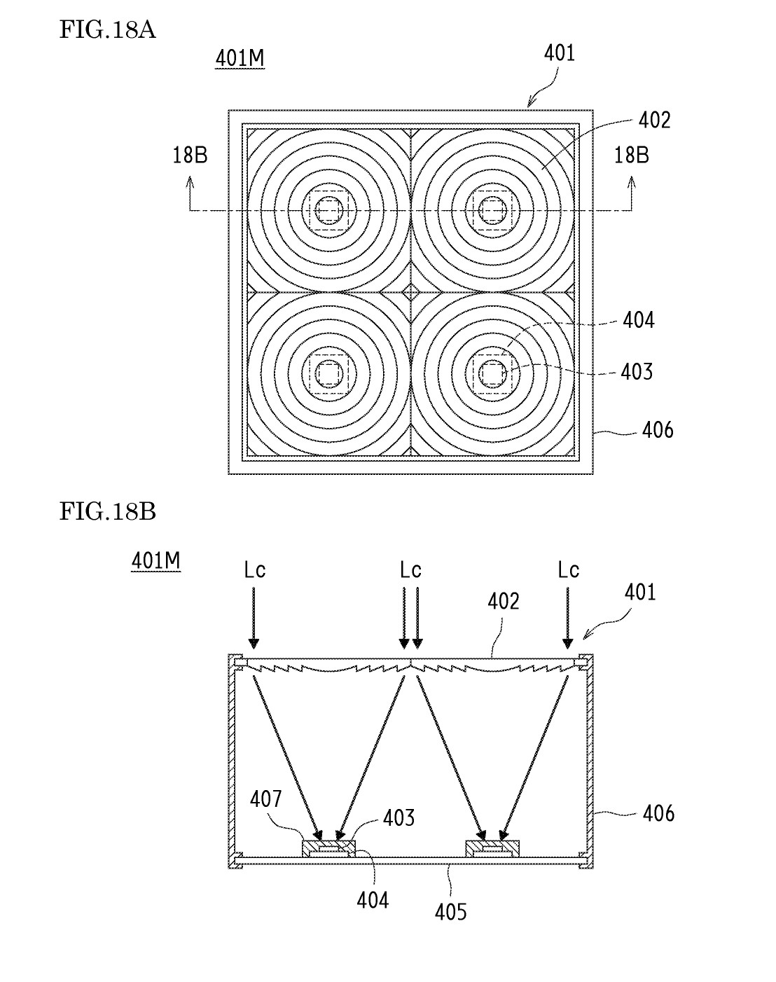

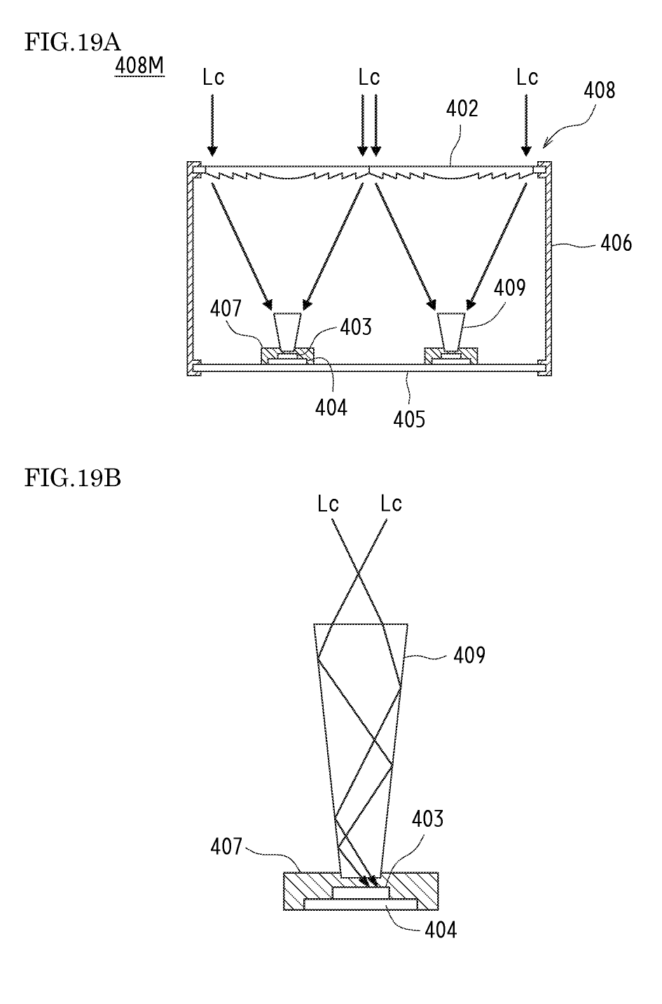

A secondary lens 300 of a fifth embodiment will be described below with reference to FIGS. 17A through 17C. This embodiment is different from the third embodiment or the fourth embodiment only in the configuration and the effect of the secondary lens 300. Accordingly, a description will be given mainly of portions of the secondary lens 300 different from those of the secondary lens 100 (third embodiment) or the secondary lens 200 (fourth embodiment). The concentrating photovoltaic power generation apparatus 30, the concentrating photovoltaic power generation module 30M, and the photovoltaic cell mounting body 1 are similar to those of the third or fourth embodiment, and an explanation thereof will thus be omitted.

FIG. 17A is a perspective view of the configuration of the secondary lens 300 of the fifth embodiment, as viewed from an obliquely upward direction.

FIG. 17B is a side view of the secondary lens 300 shown in FIG. 17A, as viewed from a side.

FIG. 17C is a sectional view of an outer peripheral configuration 306 of the secondary lens 300 at a position of line 17C-17C indicated by the arrows in FIG. 17A.

The secondary lens 300 of this embodiment is used in the concentrating photovoltaic power generation apparatus 30 and includes a light incoming section 301 on which light Lc is incident and a light outgoing section 302 from which the light Lc incident on the light incoming section 301 is output to the photovoltaic cell 3. The light incoming section 301 also includes a vertex portion 304 opposing the concentrating lens 2 and an intermediate portion 305 positioned between the vertex portion 304 and the light outgoing section 302. The cross-sectional area of the intermediate portion 305 in a direction perpendicular to the vertical axis Ax which is defined by a straight line passing through the center 2c of the concentrating lens 2 and the center 3c of the photovoltaic cell 3 increases as it approaches from the vertex portion 304 toward the light outgoing section 302. Outer peripheral configurations 306 (FIG. 17C) of at least some cross sections of the intermediate portion 305 are different from a similar figure of the edge configurations 2e of a cross section obtained by cutting through the optical refractive face H1 of the concentrating lens 2 in a plane perpendicular to the vertical axis Ax. That is, the outer peripheral configuration 306 is a rectangular (quadrilateral) and is different from a similar figure of the edge configurations 2e (circles). A base portion 303 is disposed between the light outgoing section 302 and the intermediate portion 305.

The secondary lens 300 has a three-dimensional configuration having a symmetrical arrangement which is divided into four portions about the vertical axis Ax when an intersecting point of two planes orthogonal to each other is superposed on the vertical axis Ax. The surface of the intermediate portion 305 is formed as a curved surface in a convex shape projecting from the base portion 303 to the vertex portion 304. The four surfaces (curved surfaces) of the four portions divided from the intermediate portion 305 are formed as curved surfaces such that a quadrilateral cross section (FIG. 17C) is obtained when cutting the four surfaces in a plane perpendicular to the vertical axis Ax. Ridge lines 307 are formed between the four curved surfaces.

In the secondary lens 300, a quadrilateral cross section is obtained when cutting the intermediate portion 305 in a plane perpendicular to the vertical axis Ax. Accordingly, in a side view (FIG. 17B) of the secondary lens 300 in which a curved surface is shown at the front, the ridge line 307 faithfully represents a curved state of the curved surface (intermediate portion 305). The curved state of the ridge line 307 shows that the surface of the intermediate portion 305 may be formed as part of, for example, an ellipse. Alternatively, the surface of the intermediate portion 305 may be formed as a combination of curved surfaces having different curvatures.

The secondary lens 300 may have more than four (for example, six or eight) symmetrically arranged curved surfaces.

As discussed above, the secondary lens 300 of this embodiment is the secondary lens 300 used in the concentrating photovoltaic power generation apparatus 30 that includes the photovoltaic cell 3 and the concentrating lens 2 which concentrates light Lc and applies it to the photovoltaic cell 3. The secondary lens 300 includes the light incoming section 301 on which light Lc is incident and the light outgoing section 302 from which the light Lc incident on the light incoming section 301 is output to the photovoltaic cell 3. The light incoming section 301 also includes the vertex portion 304 opposing the concentrating lens 2 and the intermediate portion 305 positioned between the vertex portion 304 and the light outgoing section 302. The cross-sectional area of the intermediate portion 305 in a direction perpendicular to the vertical axis Ax which is defined by a straight line passing through the center 2c of the concentrating lens 2 and the center 3c of the photovoltaic cell 3 increases as it approaches from the vertex portion 304 toward the light outgoing section 302. Outer peripheral configurations 306 (quadrilateral, as shown in FIG. 17C) of at least some cross sections of the intermediate portion 305 are different from a similar figure (circle, as shown in FIGS. 10B and 11B) of the edge configurations 2e of a cross section obtained by cutting through the optical refractive face H1 of the concentrating lens 2 in a plane perpendicular to the vertical axis Ax.

In the secondary lens 300 of this embodiment, the cross-sectional area of the intermediate portion 305 in a direction perpendicular to the vertical axis Ax which is defined by a straight line passing through the center 2c of the concentrating lens 2 and the center 3c of the photovoltaic cell 3 increases (monotonically increases) as it approaches from the vertex portion 304 toward the light outgoing section 302. Additionally, the outer peripheral configurations 306 of at least some cross sections of the intermediate portion 305 are different from a similar figure of the edge configurations 2e of a cross section obtained by cutting through the optical refractive face H1 of the concentrating lens 2 in a plane perpendicular to the vertical axis Ax. With this configuration, the light Lc concentrated by the concentrating lens 2 toward the secondary lens 300 is refracted by an outer peripheral configuration 306 of the intermediate portion 305, thereby preventing the light Lc from being excessively concentrated on and around the center of the photovoltaic cell 3. As a result, it is possible to suppress a decrease in FF (fill factor) which indicates the electrical characteristics of the photovoltaic cell 3 and to improve the power generation efficiency of the photovoltaic cell.

Additionally, in the secondary lens 300, the outer peripheral configuration 306 is preferably a polygon (quadrilateral). Accordingly, in the secondary lens 300, since the outer peripheral configuration 306 is a polygon, a large amount of concentrated light Lc can be refracted on the individual sides of the polygon, thereby reliably decreasing the excessive concentration of light and further suppressing a decrease in the value of FF. The polygon is not restricted to a quadrilateral, but may be a hexagon or an octagon.

In the secondary lens 300, it is preferable that at least part of the surface of the intermediate portion 305 is a curved surface. With this configuration, in the secondary lens 300, since the surface of the intermediate portion 305 includes a curved surface, part of the light Lc concentrated toward the photovoltaic cell 3 can be efficiently guided to the photovoltaic cell 3, thereby suppressing a decrease in the output current caused by a deviation of the angle of incident light or an error in assembling the photovoltaic cell 3 and thereby increasing the amount of power generation of the photovoltaic cell 3. That is, while decreasing the concentration of solar radiation by refraction, the balance between a decrease in the concentration of solar radiation and an increase in the light-concentration characteristics, which is another role of the secondary lens 300, can be implemented.

In the secondary lens 300, it is preferable that the surface of the intermediate portion 305 has ridge lines 307 and that the ridge lines 307 are chamfered. With this configuration, in the secondary lens 300, since the ridge lines of the intermediate portion 305 are chamfered, it is possible to prevent optical loss caused by scattering of light on the ridge lines 307 and to prevent the occurrence of damage when handling the secondary lens 300 in a manufacturing process.

In the secondary lens 300, the gradient of the surface of the intermediate portion 305 closer to the light outgoing section 302 is preferably greater than that of the intermediate portion 305 closer to the vertex portion 304. With this configuration, in the secondary lens 300, since the gradient of the intermediate portion 305 closer to the light outgoing section 302 is greater than that of the intermediate portion 305 closer to the vertex portion 304, the light Lc, which would reach a position far away from the center of the photovoltaic cell 3 (light-receiving surface) if the secondary lens 300 were not disposed, is refracted at a sharper angle toward the photovoltaic cell 3 in a direction toward the vertical axis Ax, thereby improving the light-concentration efficiency. Additionally, the light Lc is refracted by both of the intermediate portion 305 closer to the vertex portion 304 and the intermediate portion 305 closer to the light outgoing section 302 which have different gradients, so as to change the focal position in the direction of the vertical axis Ax, thereby making it possible to decrease the concentration of the light Lc in the direction of the vertical axis Ax (vertical direction). The gradient of the surface of the intermediate portion 305 (how much it is steep or gentle) may be defined by the angle between the surface of the intermediate portion 305 and a plane perpendicular to the vertical axis Ax.

More specifically, in the secondary lens 300, a first angle of inclination θ5 (FIG. 17B: first angle of inclination θ5<90 degrees), which is the angle of surface inclination of the intermediate portion 305 closer to the light outgoing section 302, is preferably greater than a second angle of inclination θ6 (FIG. 17B), which is the angle of surface inclination of the intermediate portion 305 closer to the vertex portion 304. With this configuration, in the secondary lens 300, since the first angle of inclination θ5 of the surface of the intermediate portion 305 closer to the light outgoing section 302 is greater than the second angle of inclination θ6 of the surface of the intermediate portion 305 closer to the vertex portion 304, the light Lc, which would reach a position far away from the photovoltaic cell 3 without the secondary lens 300, is refracted at a sharper angle, thereby improving the light-concentration efficiency.

The vertex portion 304 of the secondary lens 300 may be a plane. A portion corresponding to the vertex portion 304 may be cut in a plane perpendicular to the vertical axis Ax. With this configuration, since the vertex portion 304 is a plane, the secondary lens 300 reliably guides the light Lc concentrated toward the photovoltaic cell 3 to the photovoltaic cell 3 without excessively refracting the light Lc, thereby improving the light-concentration efficiency. It is also possible to decrease the concentration of the light Lc exhibited by the lens effect of the secondary lens 300, thereby further suppressing a decrease in the value of FF.

The vertex portion 304 of the secondary lens 300 may be a convex-shaped curved surface. With this configuration, since the vertex portion 304 is a curved surface, the secondary lens 300 efficiently guides the light Lc concentrated on the vertex portion 304 by the concentrating lens 2 to the photovoltaic cell 3 while decreasing the concentration of the light Lc as a whole. It is thus possible to suppress a decrease in the value of FF and to suppress a decrease in the output current caused by a deviation of the angle of incidence of the light Lc or a positional displacement of the photovoltaic cell 3, thereby increasing the amount of power generation of the photovoltaic cell 3. Although the curved surface of the vertex portion 304 of the secondary lens 300 is constituted by four curved surfaces (FIG. 17A), it may be constituted by a single curved surface.

The secondary lens 300 preferably includes the base portion 303 which is disposed between the light outgoing section 302 and the intermediate portion 305 and which is integrally formed with the intermediate portion 305. The configuration of the base portion 303 may be similar to that of the secondary lens 100 or 200. Advantages similar to those implemented by the base portion of the secondary lens 100 or 200 are also obtained.

As in the secondary lens 100 or 200, the secondary lens 300 may preferably include an antireflection coat. The secondary lens 300 may preferably be made from a light-transmitting optical material similar to that forming the secondary lens 100 or 200.

Advantages similar to those obtained by the secondary lens 100 of the third embodiment or the secondary lens 200 of the fourth embodiment are achieved by the secondary lens 300.

The third through fifth embodiments may be mutually applied to each other within a scope in which technical inconsistencies therebetween do not occur.

The foregoing description of the disclosed embodiments has been provided only for the purposes of illustration and description. It is not intended to be exhaustive or to limit the invention to the precise forms disclosed. It is intended that the scope of the invention be defined, not by the above-described embodiments, but by the following claims. The scope of the present invention is to be accorded the broadest interpretation so as to encompass all such modifications and equivalent structures and functions.

### REFERENCE SIGNS LIST

1 photovoltaic cell mounting body
2, 2s concentrating lens
2c center
2e, 2se edge configuration
3 photovoltaic cell
3c center
4 receiver substrate
5 holding plate
6 module frame
7 light-transmitting filler, light-transmitting-material filling portion
8 output cable
9 light-shielding sheet
10A, 10B secondary lens
11 light incoming section
11a vertex portion
12 light outgoing section
13 intermediate region
14 line of inflection
14a point of inflection
20M concentrating photovoltaic power generation module
30 concentrating photovoltaic power generation apparatus
30M concentrating photovoltaic power generation module
35 comparative secondary lens 15
35b base portion 15b
35c light incoming section 15c
37 comparative secondary lens 17
37b base portion 17b
37c light incoming section 17c
37d horizontal cross section 17d
100 secondary lens
101 light incoming section
102 light outgoing section
102c center
103 base portion
104 vertex portion
104c center
105 intermediate portion
105a intermediate section
105b intermediate section
106 outer peripheral configuration
106a outer peripheral configuration
106b outer peripheral configuration
107 ridge line
200 secondary lens
201 light incoming section
202 light outgoing section
202c center
203 base portion
203c corner section
204 vertex portion
204c center
205 intermediate portion
205a intermediate section
205b intermediate section
206 outer peripheral configuration
206a outer peripheral configuration
206b outer peripheral configuration
207 ridge line
208c curved line
208s straight line
300 secondary lens
301 light incoming section
302 light outgoing section
302c center
303 base portion
304 vertex portion
304c center
305 intermediate portion
306 outer peripheral configuration
307 ridge line
Ax optical axis, vertical axis
H1, H1s optical refractive face of concentrating lens
H2 optical refractive face of secondary lens
H2a first optical refractive face
H2b second optical refractive face
L1 dimension of side (concentrating lens)
L2 dimension of cell (photovoltaic cell)
L3 width of lens (secondary lens)
Lc light (solar radiation)
nD refractive index (D-line refractive index)
Wd work distance
θ1, θ3, θ5 first angle of inclination
θ2, θ4, θ6 second angle of inclination

1. A secondary lens used in a concentrating photovoltaic power generation module which applies light concentrated by a concentrating lens to a photovoltaic cell, the secondary lens comprising:
a first face which opposes the concentrating lens and on which a concentrated light beam output from the concentrating lens is incident; and
a second face which opposes the photovoltaic cell and from which the concentrated light beam output from the concentrating lens is output, the secondary lens guiding incident light to the photovoltaic cell through an optical refractive face provided on the first face, wherein
a cross-sectional area of the first face in a direction perpendicular to an optical axis of the concentrated light beam monotonically increases as the cross-sectional area approaches from a side of the first face closer to the concentrating lens to a side of the first face closer to the photovoltaic cell, and
at least one point of inflection at which an angle of inclination of the first face with respect to a plane perpendicular to the optical axis decreases as the angle of inclination approaches from the side of the first face closer to the concentrating lens to the side of the first face closer to the photovoltaic cell is provided.

2. The secondary lens according to claim 1, wherein a line passing through the point of inflection is positioned outside the photovoltaic cell, as viewed from above in a direction of the optical axis.

3. The secondary lens according to claim 1, wherein a cross-sectional configuration of the optical refractive face provided on the first face in a region from a vertex portion of the first face which opposes the concentrating lens to a line passing through the point of inflection in a direction perpendicular to the optical axis is similar to a cross-sectional configuration of an optical refractive face of the concentrating lens in a direction perpendicular to the optical axis.

4. The secondary lens according to claim 1, wherein a cross-sectional configuration of the optical refractive face provided on the first face in part of a region from a line passing through the point of inflection to the second face in a direction perpendicular to the optical axis is not similar to a cross-sectional configuration of an optical refractive face of the concentrating lens in a direction perpendicular to the optical axis.

5. The secondary lens according to claim 1, wherein:
the photovoltaic cell is a multi-junction compound cell; and
light of a wavelength range corresponding to a portion of the photovoltaic cell which is sensitive to a shortest wavelength range is not incident on a region from a line passing through the point of inflection of the first face to the second face.

6. The secondary lens according to claim 5, wherein a position of the point of inflection in a height direction of the secondary lens is set such that light of a specific wavelength which is output from an end of the concentrating lens and which is incident on a portion above and near the point of inflection reaches the photovoltaic cell after crossing the optical axis and such that light of a specific wavelength which is output from an end of the concentrating lens and which is incident on a portion below and near the point of inflection reaches the photovoltaic cell before crossing the optical axis.

7. The secondary lens according to claim 6, wherein the specific wavelength is 650 to 900 nm.

8. The secondary lens according to claim 5, wherein a distance from the point of inflection to the photovoltaic cell is set to be half or more of a distance from a vertex of the first face to the photovoltaic cell.

9. The secondary lens according to claim 1, wherein an intermediate region which does not optically contribute to guiding of the incident light to the photovoltaic cell is provided between the first face and the second face.

10. The secondary lens according to claim 1, wherein an antireflection coat for reducing surface reflection is disposed on a surface of the first face.

11. A photovoltaic cell mounting body comprising:
a secondary lens on which light concentrated by a concentrating lens is incident;
a photovoltaic cell which is disposed opposite the secondary lens and which performs photoelectric conversion on light output from the secondary lens; and
a receiver substrate on which the photovoltaic cell is mounted, wherein
the secondary lens is the secondary lens according to claim 1, and
a filling portion in which a translucent resin material is filled is disposed between the secondary lens and the photovoltaic cell.

12. A concentrating photovoltaic power generation unit comprising:
a concentrating lens which concentrates light;
a secondary lens from which light incident from the concentrating lens is output; and
a photovoltaic cell which performs photoelectric conversion on light output from the secondary lens,
wherein the secondary lens is the secondary lens according to claim 1.

13. A concentrating photovoltaic power generation module formed by combining a plurality of concentrating photovoltaic power generation units,
wherein each of the concentrating photovoltaic power generation units is the concentrating photovoltaic power generation unit according to claim 12.

14.-37. (canceled)
